(19) United States
(12) Patent Application Publication
(10) Pub. No.: US 2003/0077542 A1
(43) Pub. Date: Apr. 24, 2003

(54) Photopolymerizable composition, recording material and image forming method

(75) Inventors: Yoshimitsu Arai, Shizuoka-ken (JP); Yuuichi Fukushige, Shizuoka-ken (JP)

Correspondence Address: SUGHRUE MION, PLLC, Suite 800, 2100 Pennsylvania Avenue, N.W., Washington, DC, 20037-3213, US

(73) Assignee: FUJI PHOTO FILM CO., LTD.

(21) Appl. No.: 10/058,986

(22) Filed: Jan. 30, 2002

(30) Foreign Application Priority Data
Feb. 1, 2001 (JP) 2001-25684

(51) Int. Cl. G03F 7/027

(52) U.S. Cl. 430/281.1; 430/336; 430/338

(57) ABSTRACT

A photopolymerizable composition and a recording material containing the composition. The composition include at least a radical-polymerizable compound and a photopolymerization initiator, in which the photopolymerization initiator contains a borate compound, having a melting point of not more than 140° C., of the following general formula (I) in which R¹, R², R³ and R⁴ each independently represent an alkyl group, aryl group, heterocyclic group, or silyl group; and Z⁺ represents a cation.

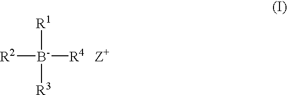

### BACKGROUND OF THE INVENTION

1. Field of the Invention

The present invention relates to a recording material, a photopolymerizable composition containing a borate compound and an image forming method.

2. Description of the Related Art

Some examples of using a combination of a borate compound and a sensitizing dye as a photopolymerization initiator have been known. For example, U.S. Pat. Nos. 4,772,530, 4,772,541 and 5,151,520 disclose triarylalkyl borates having, as the counter ion, a cationic dye such as cyanine or rhodamine. These compounds are used for photopolymerization initiators. By U.S. Pat. No. 5,055,372, to use quaternary ammonium compounds such as tetramethylammonium, pyridinium and cetylpyridinium for the counter cation of triarylalkyl borates has been known.

In photoinitiators comprising a combination of a borate compound and a sensitizing dye, the electron transfer efficiency between the dye and the borate is important for improving their sensitivity and color erasability. In general, the dye/borate compound electron transfer efficiency much depends on a potential difference between the dye and the borate compound. Further, in fact, however, the borate compound and the dye must be in a condition in which they can readily form a complex. However, if the melting point of the borate compound is outside a certain range, it is often difficult to obtain desired sensitivity or the like.

### SUMMARY OF THE INVENTION

The present invention has been made in consideration of above-mentioned problems, and its object is to provide a photopolymerizable composition and a recording material having improved sensitivity, color erasability, stability and storability.

To solve the problems noted above, the present inventors have assiduously studied, and have found that, when a borate compound having a low melting point is used, it is possible to provide a photopolymerizable composition and a recording material having improved sensitivity, color erasability, stability and storability.

The first aspect of the present invention for solving the above-mentioned problem is a photopolymerizable composition comprising at least a radical-polymerizable compound and a photopolymerization initiator. The photopolymerization initiator contains a borate compound of the following general formula (I), and the borate compound has a melting point of at most 140° C.

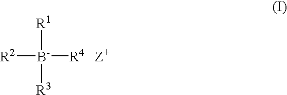

In the formula (I), R¹, R², R³ and R⁴ each independently represent an alkyl group, aryl group, heterocyclic group, or silyl group; and Z⁺ represents a cation.

The second aspect of the present invention is a recording material comprising a support and at least one recording layer. The recording layer contains a color-forming component A, a color-forming component B that reacts with the color-forming component A for forming color, and a photopolymerizable composition. The photopolymerizable composition includes at least a radical-polymerizable compound and a photopolymerization initiator, and the photopolymerization initiator which include a borate compound of the following general formula (I), and the borate compound has a melting point of not lower than 140° C.

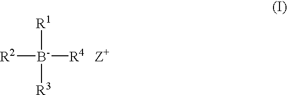

In the formula, R¹, R², R³ and R⁴ each independently represent an alkyl group, aryl group, heterocyclic group, or silyl group; and Z⁺ represents a cation.

The third aspect of the present invention is a method for forming an image. The method comprises the steps of:

preparing a recording material which has a support and at least one recording layer, the recording layer containing a color-forming component A, a color-forming component B that reacts with the color-forming component A for forming a color, and a photopolymerizable composition, the photopolymerizable composition including at least a photopolymerization initiator which includes a borate compound of the following general formula (I), the borate compound having a melting point of at most 140° C.:

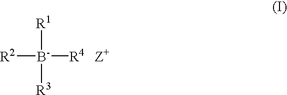

wherein R¹, R², R³ and R⁴ each independently represent an alkyl group, aryl group, heterocyclic group, or silyl group, and Z⁺ represents a cation;

forming a latent image on the recording layer by imagewise exposing the recording layer to light such that non-exposed portions of the layer form the latent image; and

visualizing the latent image by applying at least one of heat and pressure to substantially an entire surface of the recording layer so as to make the color-forming component A react with the color-forming component B at the non-exposed portion.

### DESCRIPTION OF THE PREFERRED EMBODIMENTS

The borate compound used in the present invention is described below. The borate compound for use in the invention is represented by the above-mentioned general formula (I) and has a melting point at most 140° C. Preferably, its melting point is at most 130° C., more preferably at most 120° C. If the melting point thereof is 50° C. or lower, the compound will be difficult to handle. Therefore, it is desirable that the melting point of the compound is higher than 50° C. Due to the borate compound which is comprised in the photopolymerizable composition and has a low melting point, the sensitivity and color erasability of the photopolymerizable composition is improved. It is thought that complex formation between the borate compound and a spectral sensitizing dye in the composition will be promoted due to the borate compound having a low melting point. Further, due to the borate compound having a low melting point, not only the sensitivity and the color erasability of the photopolymerizable composition but also the storability of the photopolymerizable composition can be improved.

In the formula (I) , R¹, R², R³ and R⁴ each represent an alkyl group, an aryl group, a heterocyclic group or a silyl group; Z⁺ represents a cation; and they may be the same or different from each other, and may be unsubstituted or substituted.

Preferably, the alkyl group is a linear or branched group having 1 to 30 carbon atoms, and more preferably having from 1 to 20 carbon atoms. The aryl group includes, for example, a phenyl group, a naphthyl group and an anthranyl group. The heterocyclic group is preferably an aromatic or aliphatic heterocyclic group containing at least one of a nitrogen atom, oxygen atom, sulfur atom and phosphorus atom. Examples thereof include a 2-furyl group, a furfuryl group, a 2-thienyl group, a 2-pyrrolyl group, a 2-pyridyl group, a piperidino group, a 4-piperidyl group, and a 2-quinolyl group. These groups may be further substituted with one or more substituents.

Examples of the substituent which can be applied to the alkyl group, the aryl group, the heterocyclic group or the silyl group include a halogen atom, an alkyl group, an aryl group, an alkenyl group, an alkynyl group, an alkoxy group, an aryloxy group, an alkoxycarbonyl group, an acyloxy group, an amino group, a carbamoyl group, a cyano group, an alkylsulfenyl group, an arylsulfenyl group, an alkylsulfinyl group, an arylsulfinyl group, an alkylsulfonyl group, an arylsulfonyl group, a sulfamoyl group, a carboxyl group, a sulfonic acid group, an acyl group, a silyl group, and a heterocyclic group.

An alkyl group having 1 to 30 carbon atoms is preferable as the substituent. Examples thereof include a methyl group, a trifluoromethyl group, an ethyl group, a butyl group, a hexyl group, an octyl group, a 2-ethylhexyl group, a decyl group, a dodecyl group, an octadecyl group, a propyl group, an isopropyl group, an isobutyl group, a sec-butyl group, a t-butyl group, a pentyl group, a 1-ethylpentyl group, a cyclopentyl group, a cyclohexyl group, an isopentyl group, a heptyl group, a nonyl group, an undecyl group, a t-octyl group, an ethoxycarbonylmethyl group, a butoxycarbonylmethyl group, a 2-ethylhexyloxycarbonylmethyl group, a 1-(ethoxycarbonyl)ethyl group, a 2′,4-diisopentylphenyloxymethyl group, a 2′,4′-di-t-butylphenyloxymethyl group, an ethoxycarbonylethyl group, a 2-ethylhexyloxycarbonylethyl group, a butyldecyloxycarbonylethyl group, a dibutylaminocarbonylmethyl group, a dibenzylaminocarbonylethyl group, an ethyloxycarbonylpropyl group, a 2-ethylhexyloxycarbonylpropyl group, a 2,4-di-t-amylphenyloxypropyl group, a 1-(2′,4′-di-t-amylphenyloxy)propyl group, a 2,4-di-t-butylphenyloxypropyl group, an acetylaminoethyl group, an N,N-dihexylaminocarbonylethyl group, a 2,4-di-t-amyloxyethyloxycarbonylpropyl group, an isostearyloxycarbonylpropyl group, a 1-(2,4-di-t-pentylphenyloxy)propyl group, a 2,4-di-t-pentylphenyloxyethyloxycarbonylpropyl group, a naphthyloxyethyloxycarbonylethyl group, an N-methyl-N-phenylethyloxycarbonylethyl group, and a methanesulfonylaminopropyl group.

An aryl group having 6 to 30 carbon atoms is preferable as the substituent. Examples thereof include a phenyl group, a 2-methylphenyl group, a 2-chlorophenyl group, a 2-methoxyphenyl group, a 2-ethoxyphenyl group, a 2-propoxyphenyl group, a 2-isopropoxyphenyl group, a 2-butoxyphenyl group, a 2-(2-ethylhexyloxy)phenyl group, a 2-octyloxyphenyl group, a 2-undecyloxyphenyl group, a 2-trifluoromethylphenyl group, a 2-(2-ethylhexyloxy)-5-chlorophenyl group, a 2-hexyloxy-3,5-dichlorophenyl group, a 3-(2,4-di-t-pentylphenoxyethoxy)phenyl group, a 2-(dibutylaminocarbonylethoxy)phenyl group, a 2,4-dichlorophenyl group, a 2,5-dichlorophenyl group, a 2,4,6-trimethylphenyl group, a 3-chlorophenyl group, a 3-nitrophenyl group, a 3-cyanophenyl group, a 3-trifluoromethylphenyl group, a 3-methoxyphenyl group, a 3-ethoxyphenyl group, a 3-butoxyphenyl group, a 3-(2′-ethylhexyloxy)phenyl group, a 3,4-dichlorophenyl group, a 3,5-dichlorophenyl group, a 3,4-dimethoxyphenyl group, a 3,5-dibutoxyphenyl group, a 3-octyloxyphenyl group, a 3-(dibutylaminocarbonylmethoxy)phenyl group, a 3-(di-2-ethylhexylaminocarbonylmethoxy)phenyl group, a 3-dodecyloxyphenyl group, a 4-chlorophenyl group, a 4-cyanophenyl group, a 4-nitrophenyl group, a 4-trifluoromethylphenyl group, a 4-methoxyphenyl group, a 4-ethoxyphenyl group, a 4-isopropoxyphenyl group, a 4-butoxyphenyl group, a 4-(2-ethylhexyloxy)phenyl group, a 4-isopentyloxyphenyl group, a 4-(octadecyloxy)phenyl group, a 4-benzylphenyl group, a 4-aminosulfonylphenyl group, a 4-N,N-dibutylsulfonylphenyl group, a 4-ethoxycarbonylphenyl group, a 4-(2-ethylhexyloxycarbonyl)phenyl group, a 4-t-octylphenyl group, a 4-fluorophenyl group, a 3-acetylphenyl group, a 2-acetylaminophenyl group, a 2,4-di-t-pentylphenyl group, a 4-(2-ethylhexyloxy)carbonylphenyl group, a 4-methylthiophenyl group, a 4- (4-chlorophenylthio)phenyl group, a hydroxyphenyl group, a phenylsulfonylphenyl group, a phenylsulfonyloxyphenyl group, a phenylcarbonyloxyphenyl group, a dimethylaminocarbonyloxyphenyl group, and a butylcarbonyloxyphenyl group.

An alkenyl group having 2 to 10 carbon atoms is preferable as the substituent. Examples thereof include a vinyl group, an allyl group, a styryl group, a 6-methyl-hept-3-en-2-yl group, and a 6-methyl-5-ethyl-hept-3-en-2-yl group.

An alkenyl group having 2 to 10 carbon atoms is preferable as the substituent. Examples thereof include an ethynyl group, a propynyl group, and a propargyl group.

An alkoxy group having 1 to 30 carbon atoms is preferable as the substituent. Examples thereof include a methoxy group, an ethoxy group, a propyloxy group, an isopropyloxy group, a butoxy group, an isobutoxy group, a sec-butoxy group, a t-butoxy group, a pentyloxy group, an isopentyloxy group, a hexyloxy group, a heptyloxy group, an ocytloxy group, a 2-ethylhexyloxy group, a decyloxy group, a dodecyloxy group, an octadecyloxy group, an ethoxycarbonylmethyloxy group, a 2-ethylhexyloxycarbonylmethyloxy group, an aminocarbonylmethyloxy group, an N,N-dibutylaminocarbonylethyloxy group, an N-methylaminocarbonylmethyloxy group, an n-ethylaminocarbonylmethyloxy group, an N-octylaminocarbonylmethyloxy group, an N-methyl-N-benzylaminocarbonylmethyloxy group, a benzyloxy group, and a cyanomethyloxy group.

An aryloxy group having 6 to 30 carbon atoms is preferable as the substituent. Examples thereof include a phenyloxy group, a 1-naphthyloxy group, a 2-naphthyloxy group, a 2-chlorophenyloxy group, a 2-methyloxyphenyl group, a 2-methoxyphenyloxy group, a 2-butoxyphenyloxy group, a 3-chlorophenyloxy group, a 3-trifluoromethylphenyloxy group, a 3-cyanophenyloxy group, a 3- (2-ethylhexyloxy)phenyloxy group, a 3-nitrophenyloxy group, a 4-fluorophenyloxy group, a 4-cyanophenyloxy group, a 4-butoxyphenyloxy group, a 4-(2-ethylhexyloxy)phenyloxy group, and a 4-octadecylphenyloxy group.

An alkoxycarbonyl group having 2 to 20 carbon atoms is preferable as the substituent. Examples thereof include a methoxycarbonyl group, an ethoxycarbonyl group, a propoxycarbonyl group, a butoxycarbonyl group, a hexyloxycarbonyl group, a 2-ethylhexyloxycarbonyl group, an octyloxycarbonyl group, a decyloxycarbonyl group, an octadecyloxycarbonyl group, a phenyloxyethyloxycarbonyl group, a 2,4-di-t-amylphenyloxyethyloxycarbonyl group, a 2,6-di-t-butyl-4-methylcyclohexyloxycarbonyl group, and an isostearyloxycarbonyl group.

An acyloxy group having 2 to 20 carbon atoms is preferable as the substituent. Examples thereof include an acetyloxy group, a propanoyloxy group, a butanoyloxy group, pentanoyloxy group, a trifluoromethylcarbonyloxy group, an octanoyloxy group, a decanoyloxy group, an undecanoyloxy group, and an octadecanoyloxy group.

An amino group as the substituent includes an unsubstituted amino group and a substituted amino group. Preferably, the amino group has from 0 to 50 carbon atoms in total. Examples thereof includes —NH₂, an N-alkylamino group, an N-arylamino group, an N-acylamino group, an N-sulfonylamino group, an N,N-dialkylamino group, an N,N-diarylamino group, an N-alkyl-N-arylamino group, and an N,N-disulfonylamino group. More concretely, examples include an N-methylamino group, an N-ethylamino group, an N-propylamino group, an N-isopropylamino group, an N-tert-butylamino group, an N-hexylamino group, an N-cyclohexylamino group, an N-octylamino group, an N-2-ethylhexylamino group, an N-decylamino group, an N-octadecylamino group, an N-benzylamino group, an N-phenylamino group, an N-2-methylphenylamino group, an N-2-chlorophenylamino group, an N-2-methoxyphenylamino group, an N-2-isopropoxyphenylamino group, an N-2-(2-ethylhexyloxy)phenylamino group, an N-3-chlorophenylamino group, an N-3-nitrophenylamino group, an N-3-cyanophenylamino group, an N-4-methoxyamino group, an N-4-(2′-ethylhexyloxy)phenylamino group, an N-4-cyanophenylamino group, an N-methyl-N-phenylamino group, an N,N-dimethylamino group, an N,N-dibutylamino group, an N,N-diphenylamino group, an N,N-diacetylamino group, an N,N-dibenzoylamino group, an N,N-(dibutylcarbonyl)amino group, an N,N-(di-2-ethylhexylcarbonyl)amino group, an N,N-(dimethylsulfonyl)amino group, an N,N-(diethylsulfonyl)amino group, an N,N-(dibutylsulfonyl)amino group, an N,N-(2-ethylhexylsulfonyl)amino group, and an N,N-(diphenylsulfonyl)amino group.

A carbamoyl group as the substituent includes an unsubstituted carbamoyl group and a substituted carbamoyl group. As a substituent which is added to the carbamonyl group, preferred are an alkyl group and an aryl group. Carbamoyl groups used for R¹ to R⁴ preferably have from 1 to 30 carbon atoms in total. Examples thereof include an N-methylcarbamoyl group, an N-ethylcarbamoyl group, an N-propylcarbamoyl group, an N-butylcarbamoyl group, an N-hexylcarbamoyl group, an N-cyclohexylcarbamoyl group, an N-octylcarbamoyl group, an N-2-ethylhexylcarbamoyl group, an N-decylcarbamoyl group, an N-octadecylcarbamoyl group, an N-phenylcarbamoyl group, an N-2-methylphenylcarbamoyl group, an N-2-chlorophenylcarbamoyl group, an N-2-methoxyphenylcarbamoyl group, an N-2-isopropoxyphenylcarbamoyl group, an N-2-(2-ethylhexyloxy)phenylcarbamoyl group, an N-3-chlorophenylcarbamoyl group, an N-3-nitrophenylcarbamoyl group, an N-3-cyanophenylcarbamoyl group, an N-4-methoxycarbamoyl group, an N-4-(2′-ethylhexyloxy)phenylcarbamoyl group, an N-4-cyanophenylcarbamoyl group, an N-methyl-N-phenylcarbamoyl group, an N,N-dimethylcarbamoyl group, an N,N-dibutylcarbamoyl group, and an N,N-diphenylcarbamoyl group.

An alkylsulfenyl group having 1 to 20 carbon atoms is preferable as the substituent. Examples thereof include a methylsulfenyl group, an ethylsulfenyl group, a propylsulfenyl group, an isopropylsulfenyl group, a butylsulfenyl group, a hexylsulfenyl group, a cyclohexylsulfenyl group, an octylsulfenyl group, a 2-ethylhexylsulfenyl group, a decylsulfenyl group, a dodecylsulfenyl group, an octadecylsulfenyl group, and a cyanomethylsulfenyl group.

An arylsulfenyl group having 6 to 30 carbon atoms is preferable as the substituent. Examples thereof include a phenylsulfenyl group, a 1-naphthylsulfenyl group, a 2-naphthylsulfenyl group, a 2-chlorophenylsulfenyl group, a 2-methylphenylsulfenyl group, a 2-methoxyphenylsulfenyl group, a 2-butoxyphenylsulfenyl group, a 3-chlorophenylsulfenyl group, a 3-trifluoromethylphenylsulfenyl group, a 3-cyanophenylsulfenyl group, a 3-(2-ethylhexyloxy)phenylsulfenyl group, a 3-nitrophenylsulfenyl group, a 4-fluorophenylsulfenyl group, a 4-cyanophenylsulfenyl group, a 4-butoxyphenylsulfenyl group, a 4-(2-ethylhexyloxy)phenylsulfenyl group, and 4-octadecylphenylsulfenyl group.

As alkylsulfinyl group having 1 to 20 carbon atoms is preferable as the substituent. Examples thereof include a methylsulfinyl group, an ethylsulfinyl group, a propylsulfinyl group, an isopropylsulfinyl group, a butylsulfinyl group, a hexylsulfinyl group, a cyclohexylsulfinyl group, an octylsulfinyl group, a 2-ethylhexylsulfinyl group, a decylsulfinyl group, a dodeylsulfinyl group, an octadecylsulfinyl group and a cyanomethylsulfinyl group.

An arylsulfinyl group having 6 to 30 carbon atoms is preferable as the substituent. Examples thereof include a phenylsulfinyl group, a 1-naphthylsulfinyl group, a 2-naphthylsulfinyl group, a 2-chlorophenylsulfinyl group, a 2-methylphenylsulfinyl group, a 2-methoxyphenylsulfinyl group, a 2-butoxyphenylsulfinyl group, a 3-chlorophenylsulfinyl group, a 3-trifluoromethylphenylsulfinyl group, a 3-cyanophenylsulfinyl group, a 3-(2-ethylhexyloxy)phenylsulfinyl group, a 3-nitrophenylsulfinyl group, a 4-fluorophenylsulfinyl group, a 4-cyanophenylsulfinyl group, a 4-butoxyphenylsulfinyl group, a 4-(2-ethylhexyloxy)phenylsulfinyl group, and a 4-octadecylphenylsulfinyl group.

An alkylsulfonyl group having 1 to 20 carbon atoms is preferable as the substituent. Examples thereof include a methylsulfonyl group, an ethylsulfonyl group, a propylsulfonyl group, an isopropylsulfonyl group, a butylsulfonyl group, a hexylsulfonyl group, a cyclohexylsulfonyl group, an octylsulfonyl group, a 2-ethylhexylsulfonyl group, a decylsulfonyl group, a dodecylsulfonyl group, an octadecylsulfonyl group, and a cyanomethylsulfonyl group.

An arylsulfonyl group having 6 to 30 carbon atoms is preferable as the substituent. Examples thereof include a phenylsulfonyl group, a 1-naphthylsulfonyl group, a 2-naphthylsulfonyl group, a 2-chlorophenylsulfonyl group, a 2 -methylphenylsulfonyl group, a 2 -methoxyphenylsulfonyl group, a 2-butoxyphenylsulfonyl group, a 3-chlorophenylsulfonyl group, a 3-trifluoromethylphenylsulfonyl group, a 3-cyanophenylsulfonyl group, a 3-(2-ethylhexyloxy)phenylsulfonyl group, a 3-nitrophenylsulfonyl group, a 4-fluorophenylsulfonyl group, a 4-cyanophenylsulfonyl group, a 4-butoxyphenylsulfonyl group, a 4-(2-ethylhexyloxy)phenylsulfonyl group, and a 4-octadecylphenylsulfonyl group.

A sulfamoyl group as the substituent includes an unsubstituted sulfamoyl group and a substituted sulfamoyl group. Preferably, the sulfamoyl group has from 0 to 30 carbon atoms in total. Examples thereof include a sulfamoyl group, an N-alkylsulfamoyl group, an N-arylsulfamoyl group, an N,N-dialkylsulfamoyl group, an N,N-diarylsulfamoyl group, and an N-alkyl-N-arylsulfamoyl group. More concretely, it includes an N-methylsulfamoyl group, an N-ethylsulfamoyl group, an N-propylsulfamoyl group, an n-butylsulfamoyl group, an N-hexylsulfamoyl group, an N-cyclohexylsulfamoyl group, an N-octylsulfamoyl group, an N-2-ethylhexylsulfamoyl group, n N-decylsulfamoyl group, an N-octadecylsulfamoyl group, an N-phenylsulfamoyl group, an N-2-methylphenylsulfamoyl group, an N-2-chlorophenylsulfamoyl group, an N-2-methoxyphenylsulfamoyl group, an N-2-isopropoxyphenylsulfamoyl group, an N-2-(2-ethylhexyloxy)phenylsulfamoyl group, an N-3-chlorophenylsulfamoyl group, an N-3-nitrophenylsulfamoyl group, an N-3-cyanophenylsulfamoyl group, an N-4-methoxyphenylsulfamoyl group, an N-4-(2′-ethylhexyloxy)phenylsulfamoyl group, an N-4-cyanophenylsulfamoyl group, an N-methyl-N-phenylsulfamoyl group, an N,N-dimethylsulfamoyl group, an N,N-dibutylsulfamoyl group, an N,N-diphenylsulfamoyl group, and an N,N-di(2-ethylhexyl)sulfamoyl group.

An acyl group having 2 to 20 carbon atoms is preferable as the substituent. Examples thereof include an acetyl group, a propanoyl group, a butanoyl group, a hexanoyl group, an octanoyl group, a 2-ethylhexanoyl group, a decanoyl group, a dodecanoyl group, and an octadecanoyl group.

A heterocyclic group as the substituent is preferably an aromatic or aliphatic heterocyclic group containing any of nitrogen, oxygen, sulfur and phosphorus atoms. Examples thereof include a 2-furyl group, a furfuryl group, a 2-thienyl group, a 2-pyrrolyl group, a2-pyridyl group, a piperidino group, a 4-piperidyl group and a 2-quinolyl group.

Among the compounds represented by the general formula (I) , triarylalkyl borates in which R¹, R² and R³ each are an aryl group and R⁴ is an alkyl group are preferable, and those compounds in which at least one of the aryl groups thereof has an electron-attracting group are more preferable. Concrete examples of the aryl group include a 3-fluorophenyl group, a 3-chlorophenyl group, a 5-fluoro-2-methylphenyl group, a 5-chloro-2-methylphenyl group, a 4-chloro-2-methylphenyl group, and a 3-chloro-4-methylphenyl group.

From the viewpoint of their production, preferred are triarylalkyl borates in which all the aryl groups are the same.

In general formula (I) , Z⁺ represents a group capable of forming a cation. Examples thereof include alkali metals (especially lithium or sodium), alkaline earth metals, transition metals, quaternary ammoniums, dye cations, and cationic transition metal-coordinated complex compounds. Preferably, Z⁺ is selected from ammonium, tetraalkylammoniums or dye cations. Tetraalkylammoniums are represented by the following formula.

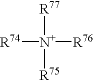

In the formula, R⁷⁴ to R⁷⁷ each represent an alkyl group. For example, they include tetramethylammonium in which R⁷⁴ to R⁷⁷ are methyl groups, tetraethylammonium in which R⁷⁴ to R⁷⁷ are ethyl groups, tetrapropylammonium in which R⁷⁴ to R⁷⁷ are propyl groups, and tetrabutylammonium in which R⁷⁴ to R⁷⁷ are butyl groups.

Also preferably, Z⁺ is a benzyltrialkylammonium shown by the following formula.

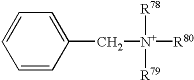

In the formula, R⁷⁸ to R⁸⁰ each represent an alkyl group. Preferred examples of the benzyltrialkylammonium are benzyltrimethylammonium, benzyltriethylammonium, benzyltripropylammonium and benzyltributylammonium. Also preferred are trisalkylammonium ions, such as trimethylamonium. Z⁺ may also be a phosphonium ion or an ammonium ion shown by the following formulae.

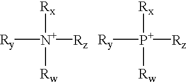

In the formulae, R_{w}, Rₓ, R_{y} and R_{z} each independently represent a hydrogen atom, or an unsubstituted or substituted alkyl, cycloalkyl, alkenyl, phenyl or arylalkyl group.

Examples of the substituent for these alkyl, cycloalkyl, alkenyl, phenyl and aralkyl groups are a halogen atom, a hydroxyl group, a heterocycloalkyl group (e.g., an epoxy group, an aziridyl group, an oxetanyl group, a furanyl group, a pyrrolidinyl group, a pyrrolyl group, a thiophenyl group, a tetrahydrofuranyl group) , a dialkylamino group, an amino group, a carboxyl group, an alkyl- or aryl-carbonyl group, and an aryloxy- or alkoxy-carbonyl group. The tetravalent nitrogen atom in the above formula may be a part of a 5-membered or 6-membered ring, and may be condensed with any other ring. These rings may have any other hetero atom such as S, N or O.

Z⁺ may also be a poly-form ammonium or phosphonium ion, that is, Z⁺ may be a polyammonium or polyphosphonium ion. Preferably, it may be a bis-form ion. As examples of the substituent of the poly-ions, preferable examples thereof are the same as those mentioned hereinabove for the substituent of the mono-ions.

The ammonium ion and the phosphonium ion may be substituted with a neutral dye (e.g., thioxanthene, thioxanthone, coumarin, and ketocoumarin). The substituted ions may be formed by a reaction of an ammonium or phosphonium ion having a reactive group (e.g., an epoxy group, an amino group, and a hydroxyl group) with a suitable neutral dye. For example, they are described in EP-A 224,967 (Quantacure QTX).

Similarly, the ammonium ion and the phosphonium ion may be substituted with a colorless electron acceptor (e.g., benzophenone). Examples of Z⁺ in which the ammonium ion is substituted with benzophenone are mentioned below, but these are not limited thereto.

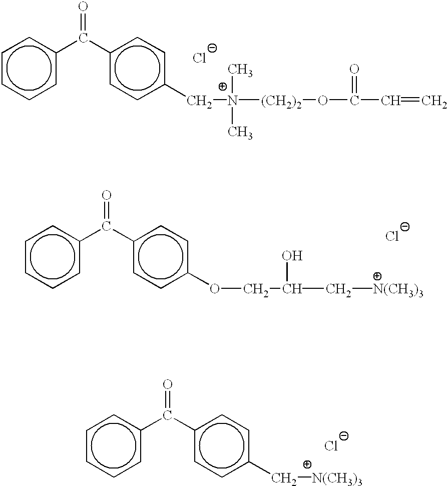

Other quaternary ammonium ions are, for example, trimethylcetylammonium ion and cetylpyridinium ion.

Other examples of Z⁺ include cations of the following cation group 1.

Cation Group 1:

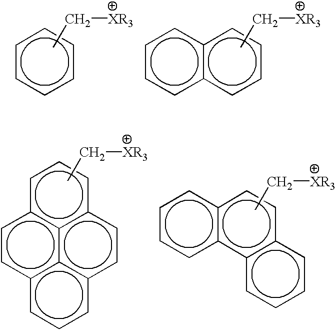

In these formulae, X represents P (phosphorus), S (sulfur) or N (nitrogen); and R represents an alkyl group or an aryl group.

Still other examples of Z⁺ include cations of the following cation group 2 or cation group 3. In the formulae shown in the cation group 2, R represents an alkyl group or an aryl group. These cations are described in Yaguchi et al's J. Polym. Sci., Part A: Polymer Chem., 1992, 30, 1987, and Polymer 1993, 34 (6), 1130. In the formulae shown in the cation group 3, R′ represents an unsubstituted or substituted benzyl or phenacyl group. These cations are disclosed in JP-A No. 7-70221. The aromatic ring in the pyridinium moiety in these cations may be substituted.

Cation Group 2:

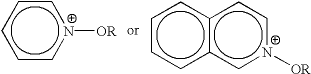

Cation Group 3:

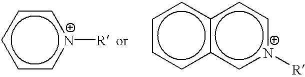

Still other examples of the counter cation Z⁺ include other onium ions such as iodonium ions and sulfonium ions. These cations are disclosed, for example, in EP-A 555,058 and EP-A 690,074, represented by the following formula:

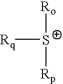

As Z⁺, following cations are also preferable.

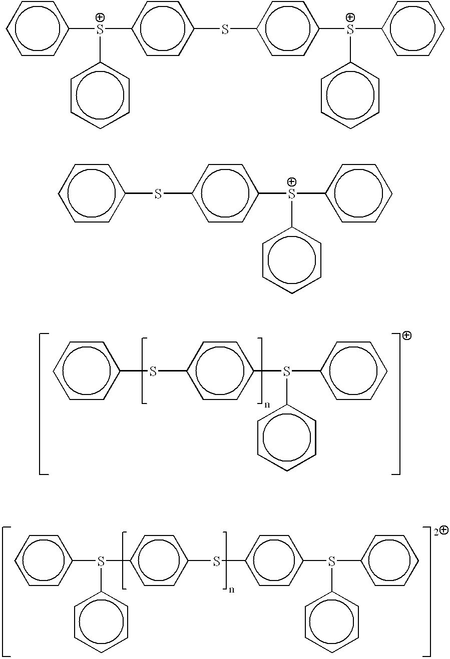

Still other examples of Z⁺ include following cations. In the following formula, R_{g} represents an alkyl group, especially an ethyl group, or a benzyl group. Further, the aromatic ring of the formula may be substituted.

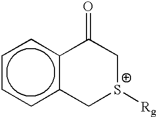

Z⁺ may also be a halonium ion. Especially preferable examples thereof are diaryliodonium ions such as those disclosed in EP-A 334,056 and EPA 562,897.

Preferable examples also include ferrocenium cations of the following formula, such as those described in EP-A 94,915 and EP-A 109,851.

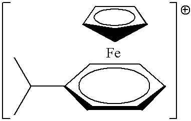

Examples of Z⁺ may also include onium ions such as ammonium ions, phosphonium ions, sulfonium ions, iodonium ions, selenonium ions, arsonium ions, telluronium ions and bismuthonium ions, such as those disclosed in JP-A No. 6-266102.

Z⁺ may also be a cationic transition metal complex compound. Examples thereof include those described in U.S. Pat. No. 4,954,414. Especially preferred are bis(2,2′-bipyridine) (4,4′-dimethyl-2,2′-bipyridine)ruthenium, tris(4,4′-dimethyl-2,2′-bipyridine)ruthenium, tris(4,4′-dimethyl-2,2′-bipyridine)iron, tris(2,2′,2″-terpyridine)ruthenium, tris(2,2′-bipyridine)ruthenium and bis(2,2′-bipyridine)(5-chloro-1,10-phenanthrine)ruthenium.

Z⁺ may also be a cationic dye such as those described in Chemistry of Functional Dyes (1981, CMC Publishing, pp. 393-416) and Colorants (60 [4] 212-224 (1987)).

Concretely, any and every cationic dye having a maximum absorption wavelength within a wavelength range of 300 or more nm, preferably from 400 nm to 1100 nm, is preferred as Z⁺. Examples of preferable cationic dyes include cationic methine dyes, polymethine dyes, triarylmethane dyes, indoline dyes, azine dyes, xanthene dyes, cyanine dyes, hemicyanine dyes, rhodamine dyes, azamethine dyes, oxazine dyes and acridine dyes. Among them, more preferable examples are cationic cyanine dyes, hemicyanine dyes, rhodamine dyes and azamethine dyes.

Z⁺ may also be a cationic polymer.

[Photopolymerizable Composition]

The photopolymerizable composition of the present invention comprises at least the borate compound specifically defined (this functions as a “photopolymerization initiator”) Further, the photopolymerizable composition preferably contains a dye and a radical-polymerizable compound. Optionally, the photopolymerizable composition may contain any other components.

(Photopolymerization Initiator)

The photopolymerizable composition of the present invention comprises, as the photopolymerization initiator, at least the borate compound represented by the general formula (I).

One or more types of the borate compound of formula (I) may be used in the composition, either singly or in combination.

When of the present invention, in case where one type of the borate compounds represented by the formula (I) where Z⁺ is not the above-mentioned cationic dye (this will be hereinafter referred to as “borate compound I”) is combined with another type of the borate compounds represented by the formula (I) where Z⁺ is any of the above-mentioned cationic dyes (hereinafter referred to as “borate compound II”), it is desirable that the two borate compounds are so combined that the ratio of the borate moiety to the cationic dye moiety in the resulting blend is at least an equimolar ratio or higher, for ensuring high sensitivity and good color erasability of the composition.

Preferably, the ratio of borate compound I/borate compound II is from 1/1 to 50/1, more preferably 1.2/1 to 30/1 and most preferably 1.2/1 to 20/1. If the ratio of the borate compound I to the borate compound II is smaller than 1/1, the radical generation will be poor, and the composition could not ensure good polymerization and color erasure; but if larger than 50/1, the composition could not ensure good sensitivity.

The borate compound content comprised in the photopolymerizable composition of the present invention is preferably 1 to 20% by weight and more preferably 4 to 15% by weight based on total weight of the radical-polymerizable compounds in the composition. The radical-polymerizable compounds are mentioned below.

If the content of the borate compound is smaller than 1% by weight, the polymerizability and the color erasability of the composition will be poor; but if the content is larger than 20% by weight, the storage stability of the composition will lower.

Within the scope of not interfering with the effect of the present invention, the photopolymerizable composition may contain any other photopolymerization initiator than the borate compound of the present invention.

Examples of other photopolymerization initiators that may be comprised in the composition include aromatic ketones such as benzophenone, 4,4-bis(dimethylamino)benzophenone, 4-methoxy-4′-dimethylaminobenzophenone, 4,4′-dimethoxybenzophenone, 4-dimethylaminobenzophenone, 4-dimethylaminoacetophenone, benzylanthraquinone, 2-tert-butylanthraquinone, 2-methylanthraquinone, xanthone, thioxanthone, 2-chlorothioxanthone, 2,4-diethylthioxanthone, fluorenone, acridone, bisacylphosphine-oxides, e.g., bis(2,4,6-trimethylbenzoyl)-phenylphosphine-oxide, acylphosphine-oxides, e.g., 2,4,6-trimethylbenzoyl-diphenylphosphine-oxide; benzoin and benzoin ethers such as benzoin methyl ether, benzoin ethyl ether, benzoin isopropyl ether, benzoin phenyl ether; 2,4,5-triarylimidazole dimers such as 2-(o-chlorophenyl)-4,5-diphenylimidazole dimer, 2-(o-chlorophenyl)-4,5-di(m-methoxyphenyl)imidazole dimer, 2-(o-fluorophenyl)-4,5-diphenylimidazole dimer, 2-(o-methoxyphenyl)-4,5-diphenylimidazole dimer, 2-(p-methoxyphenyl)-4,5-diphenylimidazole dimer; poly-halogen compounds such as carbon tetrachloride, phenyltribromomethyl sulfone, phenyltrichloromethyl ketone; compounds described in JP-A Nos. 59-133428 and 57-1819, JP-B No. 57-6096, and U.S. Pat. No. 3,615,455; S-triazine derivatives having trihalogen-substituted methyl group such as those described in JP-A No. 58-29803, for example, 2,4,6-tris(trichloromethyl)-S-triazine, 2-methoxy-4,6-bis(tricholoromethyl)-S-triazine, 2-amino-4,6-bis(trichloromethyl)-S-triazine, 2-(p-methoxystyryl)-4,6-bis(trichloromethyl)-S-triazine; organic peroxides described in JP-A No. 59-189340 such as methylethyl ketone peroxide, cyclohexanone peroxide, 3,3,5-trimethylcyclohexanone peroxide, benzoyl peroxide, di-tert-butyl diperoxyisophthalate, 2,5-dimethyl-2,5-di(benzoylperoxy)hexane, tert-butyl peroxybenzoate, α, α′-bis(tert-butylperoxyisopropyl)benzene, dicumyl peroxide and 3,3′,4,4′-tetra(tert-butylperoxycarbonyl)benzophenone; azinium salt compounds described in U.S. Pat. No. 4,743,530; organoboron compounds described in EP 223,587, such as tetramethylammonium salt of triphenylbutylborate, tetrabutylammonium salt of triphenylbutylborate and tetramethylammonium salt of tri(p-methoxyphenyl)butylborate; and other diaryliodonium salts and iron-arene complexes.

Combinations of two or more different types of compounds are known as the photopolymerization initiator, and are usable in the photopolymerizable composition of the present invention.

Examples of combinations of two or more different types of compounds include a combination of a 2,4,5-triarylimidazole dimer and mercaptobenzoxazole; a combination of 4,4′-bis(dimethylamino)benzophenone and benzophenone or benzoin methyl ether as disclosed in U.S. Pat. No. 3,427,161; a combination of benzoyl-N-methylnaphthothiazoline and 2,4-bis(trichloromethyl)-6-(4′-methoxyphenyl)triazole as disclosed in U.S. Pat. No. 4,239,850; a combination of a dialkylaminobenzoate and dimethylthioxanthone as disclosed in JP-A No. 57-23602; and a combination of three compounds such as a combination of 4,4′-bis(dimethylamino)benzophenone, benzophenone and a polyhalogenomethyl compound as in JP-A No. 59-78339.

One or more borate compounds other than those of the present invention may also be added to the composition of the present invention as a photopolymerization initiator, in so far as the compounds are not interfering with the effect of the present invention.

Examples of other borate compounds include organic borate compounds described in JP-A Nos. 62-143044, 9-188685, 9-188686 and 9-188710, and spectral sensitizing dye-type borate compounds derived which are obtained from cationic dyes.

(Dye)

Preferably, the photopolymerizable composition of the present invention contains a dye.

The dye is preferably a spectral sensitizing dye that has a maximum absorption wavelength within a range of from 300 nm to 1000 nm. By containing the spectral sensitizing dye with the borate compound of the present invention, the composition becomes highly sensitized to the source of light that falls within the range of the spectral absorption wavelength of the dye, and therefore, sensitivity of the composition is increased. In addition, the radical generation in the composition can be controlled by the use of any desired light source falling within a range of UV to IR rays.

However, in cases where the borate compound of the present invention is the above-mentioned borate compound II, that is, in cases where the borate compound is a compound having two functions since the compound has in its structure both of a dye moiety having a maximum absorption wavelength of from 300 nm to 1000 nm and a borate moiety, the above-mentioned spectral sensitizing dye may be not used in the composition.

From all spectral sensitizing dyes falling within the above-mentioned absorption wavelength range, some desired ones can be selected and used in the composition of the present invention for controlling the wavelength range to which the composition is sensitive. Due to the selection, the composition can be compatible with the light source to be used, whereby the sensitivity of the composition can be increased. In addition, due to the selection, any of blue, green or red light sources and IR lasers can be selected as the light source for image-forming exposure.

Therefore, for example, when the composition is comprised in a multi-color recording material wherein monochromatic recording layers that are each to form different colors are laminated to form a color image, spectral sensitizing dyes each having different absorption wavelengths can be selected and be separately comprised in different monochromatic layers that are to form different colors, and light sources suitable to the different absorption wavelengths can be selected and used. In that manner, even if a recording material having such a laminate structure of different recording layers is utilized, each layer (to form its own color) can have increased sensitivity and can form a sharp image of its own color due to the selection. As a whole, therefore, the multi-color recording material has increased sensitivity and can form a sharp and high-contrast multi-color image. That is, the recording material can have a laminate structure wherein plural recording layers that form different colors (hues) one another are laminated.

Any known cationic dyes, neutral dyes or anionic dyes can be used as the spectral sensitizing dyes.

Examples of such known spectral sensitizing dyes include those described in Research Disclosure, Vol. 200 (December 1980), Item 20036; and Sensitizers (pp. 160-163, Kodansha, edited by Katumi Tokumaru and Shin Ohgawara, 1987). Any of these are usable in the present invention.

Concrete examples thereof include 3-ketocoumarin compounds described in JP-A No. 58-15603; thiopyrylium salts described in JP-A No. 58-40302; naphthothiazole-merocyanine compounds described in JP-B Nos. 59-28328 and 60-53300; and merocyanine compounds described in JP-B Nos. 61-9621, 62-3842, and JP-A Nos. 59-89303, 60-60104.

Also usable dyes described in “Chemistry of Functional Dyes” (1981, CMC Publishing, pp. 393-416), and “Colorants” (60 [4] 212-224 (1987)). Concrete examples thereof include cationic methine dyes, cationic carbonium dyes, cationic quinonimine dyes, cationic indoline dyes, and cationic styryl dyes.

Examples of the spectral sensitizing dyes further include keto dyes such as coumarin (including ketocoumarin and sulfocoumarin) dyes, merostyryl dyes, oxonole dyes, hemioxonole dyes; non-keto dyes such as triarylmethane dyes, xanthene dyes, anthracene dyes, rhodamine dyes, acridine dyes, aniline dyes, azo dyes; non-ketopolymethine dyes such as azomethine dyes, cyanine dyes, carbocyanine dyes, dicarbocyanine dyes, tricarbocyanine dyes, hemicyanine dyes, styryl dyes; and quinonimine dyes such as azine dyes, oxazine dyes, thiazine dyes, quinoline dyes, thiazole dyes.

By suitably selecting and using any of the above-mentioned spectral sensitizing dyes, the spectral sensitivity of the photopolymerization initiator used in the photopolymerizable composition of the present invention can be controlled to fall within a range of UV to IR rays.

One or more types of spectral sensitizing dyes may be used in the composition, either singly or in combination.

In the composition of the present invention, the ratio of the spectral sensitizing dye to the borate compound of the invention is extremely important for increasing the sensitivity of the composition and for obtaining good color erase ability when the composition is comprised in a recording material and exposed to light in a step of image fixation.

In addition to a ratio of spectral sensitizing dye/borate compound (=1/1 by mol) which is necessary for photopolymerization reaction to occur in the composition, it is desirable that the amount of the borate compound added is enough to satisfactorily erase the color of the spectral sensitizing dye that remains in a layer of a recording material in order that good sensitivity and color erasability are achieved.

Specifically, a ratio of spectral sensitizing dye/borate compound in the composition preferably is 1/1 to 1/50, more preferably 1/1.2 to 1/30, most preferably 1/1.2 to 1/20. If the ratio of the spectral sensitizing dye to the borate compound therein is larger than 1/1, the composition could not have good polymerization ability and color erase ability therein, but if smaller than 1/50, the coatability of the composition will deteriorate.

The total amount of the spectral sensitizing dye and the borate compound in the composition preferably is 0.1 to 25% by weight, more preferably 0.1 to 20% by weight, most preferably 0.1 to 15% by weight of the total weight of the radical-polymerizable compound therein. If it is smaller than 0.1% by weight, the effect of the present invention could not be attained; but if larger than 25% by weight, the storage stability of the composition will deteriorate and the coatability thereof will also deteriorate.

When the photopolymerizable composition of the present invention is used in a recording layer of a recording material, the content of the spectral sensitizing dye preferably is 0.1 to 5% by weight, more preferably 0.5 to 2% by weight of the total weight of the recording layer.

The spectral sensitizing dye and the borate compound may be added to the coating liquid for a recording layer after being previously mixed; or the spectral sensitizing dye and the borate compound may be separately added to the coating liquid when the coating liquid is prepared.

(Radical-polymerizable Compound)

The photopolymerizable composition of the present invention preferably contains a radical-polymerizable compound. In cases where the photopolymerizable composition of the present invention is used in a recording material, the radical-polymerizable compound therein is comprised for enhancing the durability of recorded images and for improving the sensitivity of the recording material.

The radical-polymerizable compound has at least one ethylenic unsaturated bond in a chemical structure thereof. Preferably, the chemical structure of the compound has the form of monomers, prepolymers (dimers, trimers and their oligomers), or their mixtures or copolymers.

Examples of the compound are unsaturated carboxylic acids and their salts, esters of unsaturated carboxylic acids and aliphatic polyalcohols, and amides of unsaturated carboxylic acids and aliphatic polyamines.

Concretely, examples of the unsaturated carboxylic acids include acrylic acid, methacrylic acid, itaconic acid, crotonic acid, isocrotonic acid, and maleic acid.

Concretely, examples of the salts of unsaturated carboxylic acids include sodium or potassium salts of unsaturated carboxylic acids such as those mentioned above.

Examples of the esters of unsaturated carboxylic acids with aliphatic polyalcohols include acrylates, methacrylates, itaconates, crotonates, and isocrotonates. These are described more concretely below.

Examples of the acrylates include ethylene glycol diacrylate, triethylene glycol triacrylate, 1,3-butanediol diacrylate, tetramethylene glycol diacrylate, propylene glycol diacrylate, trimethylolpropane triacrylate, trimethylolethane triacrylate, 1,4-cyclohexanediol diacrylate, pentaerythritol diacrylate, pentaerythritol triacrylate, pentaerythritol tetraacrylate, dipentaerythritol diacrylate, dipentaerythritol triacrylate, dipentaerythritol tetraacrylate, sorbitol triacrylate, sorbitol tetraacrylate, sorbitol pentaacrylate, sorbitol hexaacrylate, and polyester acrylate oligomers.

Examples of the methacrylates include tetramethylene glycol dimethacrylate, triethylene glycol dimethacrylate, trimethylolpropane trimethacrylate, trimethylolethane trimethacrylate, ethylene glycol dimethacrylate, 1,3-butanediol dimethacrylate, pentaerythritol dimethacrylate, pentaerythritol trimethacrylate, dipentaerythritol dimethacrylate, sorbitol tetramethacrylate, bis-[p-(3-methacryloxy-2-hydroxypropoxy)phenyl]dimethylmethane, and bis-[p-(acryloxyethoxy)phenyl]dimethylmethane.

Examples of the itaconates include ethylene glycol diitaconate, propylene glycol diitaconate, 1,3-butanediol diitaconate, 1,4-butanediol diitaconate, tetramethylene glycol diitaconate, pentaerythritol diitaconate, and sorbitol tetraitaconate.

Examples of the crotonates include ethylene glycol dicrotonate, tetramethylene glycol dicrotonate, pentaerythritol dicrotonate, and sorbitol tetracrotonate.

Examples of the isocrotonates include ethylene glycol diisocrotonate, pentaerythritol diisocrotonate, and sorbitol tetraisocrotonate. Examples of the maleates include, for example, ethylene glycol dimaleate, triethylene glycol dimaleate, pentaerythritol dimaleate, and sorbitol tetramaleate.

These esters may be used either singly or in combination of two or more.

Concrete examples of the amides of unsaturated carboxylic acids with aliphatic polyamines include methylenebis-acrylamide, methylenebis-methacrylamide, 1,6-hexamethylenebis-acrylamide, 1,6-hexamethylenebis-methacrylamide, diethylenetriamine-trisacrylamide, xylylenebis-acrylamide, and xylylenebis-methacrylamide.

In addition to the above, vinylurethane compounds having in a molecule at least two polymerizable vinyl groups is also usable as a radical-polymerizable compound. The vinylurethane compounds are produced by adding a vinyl monomer of the following general formula to a polyisocyanate compound having in a molecule at least two isocyanate groups, and are described in JP-B No. 48-41708.

CH₂=C(R)COOCH₂CH(R)OH

In the formula, R represents H or CH₃.

Further, polymer compounds having a vinyl or vinylidene group are also usable as a radical-polymerizable compound. Examples thereof include condensates of polymer compounds having, in the side chains or the like, any of hydroxyl, amino, epoxy or sulfonyloxy groups or halogen atoms with acrylic acid, methacrylic acid or their derivatives.

The above-mentioned radical-polymerizable compounds may be used singly or in combination of two or more.

The content of the radical-polymerizable compound in the photopolymerizable composition of the present invention is preferably 10 to 50 parts by weight, more preferably 20 to 40 parts by weight, relative to one part by weight of the borate compound therein. If the content is smaller than 10 parts by weight, the color density of the recording material that contains the composition will below, and if larger than 50 parts by weight, the storage stability of the composition will lower.

(Other Components)

The photopolymerizable composition of the present invention may contain any other components serving as an aid for accelerating the polymerization reaction therein. The additional components are, for example, reducing agents such as oxygen scavengers or chain transfer agents for active hydrogen donors, and other compounds having the ability to promote chain transfer polymerization.

Examples of the oxygen scavengers include phosphines, phosphonates, phosphites, argentous salts, and other compounds capable of being readily oxidized by oxygen.

Concretely, examples thereof include N-phenylglycine, trimethylbarbituric acid, N,N-dimethyl-2,6-diisopropylaniline, and N,N,N-2,4,6-pentamethylanilinicacid. In addition, thiols, thioketones, trihalomethyl compounds, lophine dimers, iodonium salts, sulfonium salts, amidinium salts, organic peroxides, and azides are also usable as polymerization promoters.

The photopolymerizable composition of the present invention is favorable to the recording material of the present invention mentioned hereinafter. Since the photopolymerizable composition contains the borate compound of the present invention, therefore, even when the recording material containing the composition of the present invention further contains an oxygen-containing medium along with the composition, sensitivity and storage stability of the recording material are high owing to the stereo-protective effect of the borate compound in the composition.

[Recording Material]

The recording material of the present invention has a recording layer on a support, and optionally can have any other layers.

(Recording Layer)

The recording layer contains the photopolymerizable composition of the present invention mentioned above, a color-forming component A, and a color-forming component B that reacts with the color-forming component A to make the color-forming component A form a color, and optionally contains any other components.

In the recording layer, the photopolymerizable composition of the present invention mentioned above is meant to indicate the photopolymerizable composition containing at least the borate compound of the present invention, or a photopolymerizable composition containing at least the borate compound of the present invention, a dye and a radical-polymerizable compound. Concretely, when the borate compound of the present invention in the composition is a spectral sensitizing dye-type borate compound (borate compound II) obtained from cationic dyes, the composition does not require any additional dye. When the color-forming component B in the recording layer is a compound having a polymerizable group, the composition to be in the layer does not require any additional, radical-polymerizable compound. In this case, the polymerizable group-having, color-forming component B serves also as a radical-polymerizable compound.

Color-forming Component A and Color-forming Component B

The color-forming component A and the color-forming component B that reacts with the color-forming component A for forming color can be both substantially colorless, and before processing, they are highly transparent.

Preferably, at least one of the color-forming components A and B is encapsulated in microcapsules, from the viewpoint of the stability of the recording material before processing, the fog resistance of the material and the durability of the images. Also preferably, the two components are brought into contact with each other under heat and/or pressure.

Examples of the combination of the two components (color-forming component A and color-forming component B) comprised in the recording layer are the following (a) to (r) (In these examples, the former is the color-forming component A and the latter is the color-forming component B.)

(a) A combination of an electron-donating dye precursor, and an electron-receiving compound.

(b) A combination of a diazonium salt compound, and a coupling component (hereinafter referred to as “coupler”).

(c) A combination of a metal salt of an organic acid such as silver behenate or silver stearate, and a reducing agent such as protocatechic acid, spiroindane or hydroquinone.

(d) A combination of an iron salt of a long-chain fatty acid such as ferric stearate or ferric myristate, and a phenol such as tannic acid, gallic acid or ammonium salicylate.

(e) A combination of a heavy metal salt of an organic acid, such as nickel, cobalt, lead, copper, iron, mercury or silver acetate, stearate or palmitate, and an alkali metal or alkaline earth metal sulfide such as calcium sulfide, strontium sulfide or potassium sulfide; or a combination of the above-mentioned heavy metal salt of an organic acid, and an organic chelating agent such as s-diphenylcarbazide or diphenylcarbazone.

(f) A combination of a heavy metal sulfate such as silver, lead, mercury or sodium sulfate, and a sulfur compound such as sodium tetrathionate, sodium thiosulfate or thiourea.

(g) A combination of a ferric salt of a fatty acid such as ferric stearate, and an aromatic polyhydroxy compound such as 3,4-hydroxytetraphenylmethane.

(h) A combination of a metal salt of an organic acid such as silver oxalate or mercury oxalate, and an organic polyhydroxy compound such as polyhydroxyalcohol, glycerin or glycol.

(i) A combination of a ferric salt of a fatty acid such as ferric pelargonate or ferric laurate, and a thiocesylcarbamide or isothiocesylcarbamide derivative.

(j) A combination of a lead salt of an organic acid such as lead caproate, lead pelargonate or lead behenate, and a thiourea derivative such as ethylenethiourea or N-dodecylthiourea.

(k) A combination of a heavy metal salt of a higher fatty acid such as ferric stearate or copper stearate, and a zinc dialkyldithiocarbamate.

(l) A combination to form an oxazine dye, such as a combination of resorcinol and a nitroso compound.

(m) A combination of a formazan compound, and a reducing agent and/or a metal salt.

(n) A combination of a protected dye (or leuco dye) precursor, and a deprotecting agent.

(o) A combination of an oxidizable color former, and an oxidizing agent.

(p) A combination of at least one of phthalonitriles and at least one of diiminoisoindolines. (This is a combination to form a phthalocyanine.)

(q) A combination of at least one of isocyanates and at least one of diiminoisoindolines. (This is a combination to form a color pigment.)

(r) A combination of a pigment precursor, and an acid or a base. (This is a combination to form a pigment.)

As the combinations of the two components of the color-forming component A and the color-forming component B, the combination (a) of an electron-donating dye precursor and an electron-receiving compound, the combination (b) of a diazonium salt compound and a coupler, the combination (c) of an organic metal salt and a reducing agent, and the combination (n) of a protected dye (or leuco dye) precursor and a deprotecting agent are preferable.

The combinations (a), (b) and (c) preferred for the recording layer are described in detail hereinafter.

(a) Combination of electron-donating dye precursor and electron-receiving compound:

The electron-donating dye precursor preferred for use in the present invention is not specifically defined, in so far as the precursor that is provided is substantially colorless. The precursor has a property to release en electron or to receive a proton, for example, from acids, to thereby form a color. Its preferred examples are phthalide compounds, fluoran compounds, thiazine compounds, leucoauramine compounds, rhodamine-lactam compounds, spiropyran compounds, pyridine compounds, pyrazine compounds, and fluorene compounds.

As the phthalide compounds, examples include those described in U.S. Pat. No. (reissued) 23,024, U.S. Pat. Nos. 3,491,111, 3,491,112, 3,491,116, and 3,509,174. Concretely, examples thereof include 3,3-bis(p-dimethylaminophenyl)-6-dimethylaminophthalide, 3,3-bis(p-diethylaminophenyl)phthalide, 3-(p-diethylaminophenyl)-3-(1-ethyl-2-methylindol-3-yl)-4-azaphthalide, and 3,3-bis(1-octyl-2-methylindol-3-yl)phthalide.

As the fluoran compounds, examples thereof include those described in U.S. Pat. Nos. 3,624,107, 3,627,787, 3,641,011, 3,462,828, 3,681,390, 3,920,510 and 3,959,571. Concretely, examples include 2-(dibenzylamino)fluoran, 2-anilino-3-methyl-6-diethylaminofluoran, 2-anilino-3-methyl-6-dibutylaminofluoran, 2-anilino-3-methyl-6-N-ethyl-N-isoamylaminofluoran, 2-anilino-3-methyl-6-N-methyl-N-cyclohexylaminofluoran, 2-anilino-3-chloro-6-diethylaminofluoran, 2-anilino-3-methyl-6-N-ethyl-N-isobutylaminofluoran, 2-anilino-6-dibutylaminofluoran, 2-anilino-3-methyl-6-N-methyl-N-tetrahydrofurfurylaminofluoran, 2-anilino-3-methyl-6-piperidinoaminofluoran, 2-(o-chloroanilino)-6-diethylaminofluoran, and 2-(3,4-dichloroanilino)-6-diethylaminofluoran.

As the thiazine compounds, examples thereof include benzoyl-leucomethylene blue, and p-nitrobenzyl-leucomethylene blue.

As the leucoauramine compounds, examples thereof include 4,4′-bis-dimethylaminobenzhydryl benzyl ether, N-halophenyl-leucoauramine, and N-2,4,5-trichlorophenyl-leucoauramine.

As the rhodamine-lactam compounds, examples thereof include rhodamine-B-anilinolactam, and rhodamine-(p-nitryl)lactam.

As the spiropyran compounds, examples thereof include those described in U.S. Pat. No. 3,971,808. Concretely, examples thereof include 3-methyl-spiro-dinaphthopyran, 3-ethyl-spiro-dinaphthopyran, 3,3′-dichloro-spiro-dinaphthopyran, 3-benzylspiro-dinaphthopyran, 3-methyl-naphtho-(3-methoxy-benzo)spiropyran, and 3-propyl-spiro-dibenzopyran.

As the pyridine compounds and the pyrazine compounds, examples thereof include those described in U.S. Pat. Nos. 3,775,424, 3,853,869 and 4,246,318.

As the fluorene compounds, examples thereof include those described in Japanese Patent Application No. 61-240989.

The content of the electron-donating dye precursor to be comprised in the recording layer preferably is in a range from 0.1 to 5 g/m², more preferably 0.1 to 3 g/m². If the content thereof is smaller than 0.1 g/m², the color density of the layer will be low; but if larger than 5 g/m², the coatability of the coating liquid to form the layer will be poor.

In cases where plural electron-donating dye precursors which each form a color of cyan, magenta or yellow are used in the recording layers of the recording material of the present invention, the material can be used as a full-color recording material.

As cyan, magenta and yellow color-forming dyes, those described in U.S. Pat. No. 4,800,149 are usable.

As yellow color-forming electron-donating dye precursors, those described in U.S. Pat. No. 4,800,148 are also usable; and as cyan color-forming electron-donating dye precursors, those described in JP-A No. 63-53542 are also usable.

As the electron-receiving compound that reacts with the electron-donating dye precursor to form a color, examples include hydroxybenzoic acids, ester compounds, phenol derivatives, salicylic acid derivatives, metal salts of aromatic carboxylic acids, acidic clay, bentonite, novolak resins, metal-processed novolak resins, and metal complexes.

Concrete example thereof include those described in JP-A Nos. 4-226455, 63-173682, 59-83693, 60-141587, 62-99190; EP 29,323; JP-A Nos. 62-167077, 62-16708, 63-317558; JP-B No. 40-9309, 45-14039; and JP-A 52-140483, 48-51510, 57-210886, 58-87089, 59-11286, 60-176795 and 61-95988. The electron-receiving compound for use herein may have a polymerizable group.

The amount of the electron-receiving compound to be in the recording layer is preferably 0.1 to 30 parts by weight, more preferably 0.5 to 15 parts by weight, relative to one part by weight of the electron-donating dye precursor in the layer. If the amount is smaller than 0.1 parts by weight, the color density of the layer will be low; but if larger than 30 parts by weight, the sensitivity of the layer will lower and the coatability of the coating liquid to form the layer will be poor.

(b) Combination of diazonium salt compound and coupler:

The diazonium salt compound couples with the coupler as a coupling component(this is described hereinafter) to form a desired color. The diazonium salt compound is a photo-decomposable compound such that, when the diazonium salt compound receives light that falls within a specific wavelength range before it has reacted with such a coupler, the diazonium salt compound decomposes and loses its ability and can not couple with the coupling component to form a color even if it is brought into contact with a coupler after having been exposed to the light.

The color of the color-forming system is determined by the azo dye to be formed through the reaction of the diazonium salt compound and the coupler in the system. Accordingly, it is easy to control the maximum absorption wavelength that determines the color to be formed in the system, by varying the chemical structure such as position and/or type of a substituent of the diazonium salt compound or the coupler to be used in the system. Depending on the combination of the diazonium salt compound and the coupler in the system, the color to be formed in the system is varied in any desired manner.

The photo-decomposable diazonium salt preferably used in the present invention is, for example, an aromatic diazonium salt of the following formula:

Ar−N₂⁺X⁻

wherein Ar represents a substituted or unsubstituted aryl group; and X⁻ represents an acid anion.

In the formula, Ar represents a substituted or unsubstituted aryl group. Examples of the substituent for the group include an alkyl group, an alkoxy group, an alkylthio group, an aryl group, an aryloxy group, an arylthio group, an acyl group, an alkoxycarbonyl group, a carbamoyl group, a carbamido group, a sulfonyl group, a sulfamoyl group, a sulfonamido group, an ureido group, an amino group, a heterocyclic group, a cyano group, a nitro group, an a halogen atom. These substituents may be further substituted.

Preferably, Ar is an aryl group having from 6 to 30 carbon atoms. Examples thereof include a phenyl group, a 2-methylphenyl group, a 2-chlorophenyl group, a 2-methoxyphenyl group, a 2-butoxyphenyl group, a 2-(2-ethylhexyloxy)phenyl group, a 2-octyloxyphenyl group, a 3-(2,4-di-t-pentylphenoxyethoxy)phenyl group, a 4-chlorophenyl group, a 2,5-dichlorophenyl group, a 2,4,6-trimethylphenyl group, a 3-chlorophenyl group, a 3-methylphenyl group, a 3-methoxyphenyl group, a 3-butoxyphenyl group, a 3-cyanophenyl group, a 3-(2-ethylhexyloxy)phenyl group, a 3,4-dichlorophenyl group, a 3,5-dichlorophenyl group, a 3,4-dimethoxyphenyl group, a 3-(dibutylaminocarbonylmethoxy)phenyl group, a 4-cyanophenyl group, a 4-methylphenyl group, a 4-methoxyphenyl group, a 4-butoxyphenyl group, a 4-(2-ethylhexyloxy)phenyl group, a 4-benzylphenyl group, a 4-aminosulfonylphenyl group, a 4-N,N-dibutylaminosulfonylphenyl group, a 4-ethoxycarbonylphenyl group, a 4-(2-ethylhexylcarbonyl)phenyl group, a 4-fluorophenyl group, a 3-acetylphenyl group, a 2-acetylaminophenyl group, a 4-(4-chlorophenylthio) phenyl group, a 4-(4-methylphenyl)thio-2,5-butoxyphenyl group, and a 4-(N-benzyl-N-methylamino)-2-dodecyloxycarbonylphenyl group.

These groups may be further substituted, for example, with any of an alkyloxy group, an alkylthio group, a substituted phenyl group, a cyano group, a substituted amino group, a heterocyclic group, a halogen atom and the like.

Preferably, the diazonium salt compounds preferred for use in the present invention have at least 12 carbon atoms in one molecule and have a solubility in water of at most 1% and a solubility in ethyl acetate of at least 5%.

Examples of the diazonium salt compounds preferred for use in the recording material of the present invention are mentioned below, to which, however, the present invention is not limited.

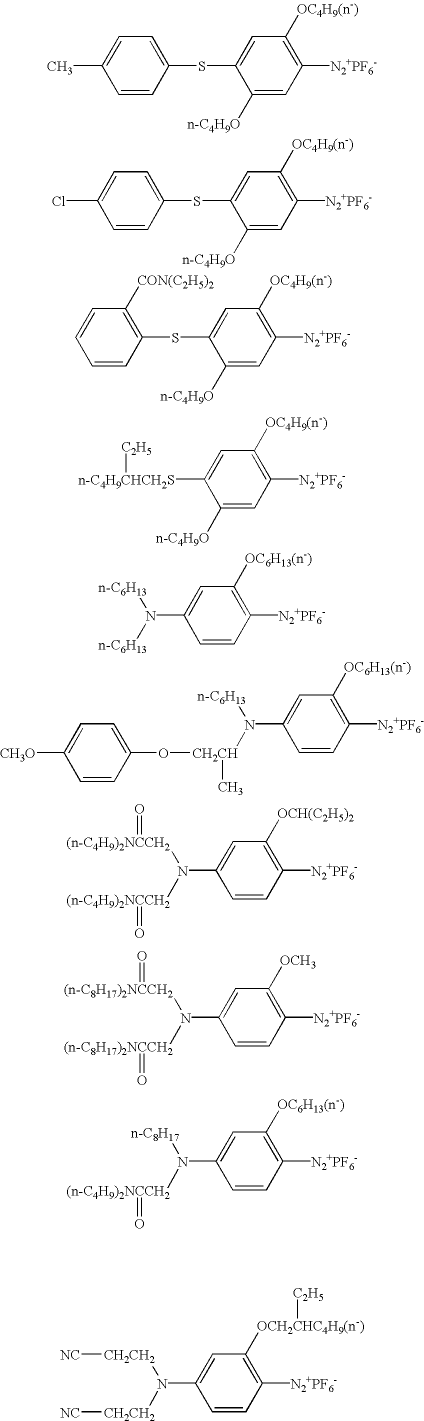

In the present invention, one or more different types of diazonium salt compounds may be used either singly or in combination in accordance with the object of color control, etc.

The content of the diazonium salt compound to be used in the recording layer is preferably 0.01 to 3 g/m², more preferably 0.01 to 2 g/m² and most preferably 0.02 to 1.0 g/m². If the content is smaller than 0.01 g/m², it is unfavorable since the recording layer could not form good color; but if larger than 3 g/m², it is also unfavorable since the sensitivity of the layer will lower and the time for image fixation in the layer will have to be long.

As the coupler to couple with the diazonium salt compound, any one capable of coupling with the diazonium salt compound to form a color in a basic atmosphere and/or in a neutral atmosphere is usable. One or more different types of such couplers are used in the present invention, either singly or in combination in accordance with the object such as color control, etc.

The couplers of the type usable herein are described in, for example, Research Disclosure No. 17643, VII-C to G, and No. 307105, VII-C to G. Preferred are non-diffusive type couplers having a hydrophobic group generally referred to as a ballast group, or polymer couplers.

Preferred examples of cyan couplers for use in the present invention include naphthol type couplers and phenol type couplers such as those described in U.S. Pat. Nos. 2,369,929, 2,772,162, 2,801,171, 2,895,826, 3,446,622, 3,758,308, 3,772,002, 4,052,212, 4,126,396, 4,146,396, 4,228,233, 4,254,212, 4,296,199, 4,296,200, 4,327,173, 4,333,999, 4,334,011, 4,343,011, 4,427,767, 4,451,559, 4,690,889 and 4,775,616; German Patent Laid-Open No. 3,329,729; EP 121,365A, 249,453A; and JP-A No. 61-42658.

Examples of magenta couplers usable in the present invention include imidazole[1,2-b]pyrazoles such as those described in U.S. Pat. No. 4,500,630, and pyrazolo[1,5-b] [1,2,4]triazoles such as those described in U.S. Pat. No. 4,540,654

Additional examples include pyrazolotriazole couplers having a branched alkyl group directly bonded to the 2-, 3- or 6-position of the pyrazolotriazole ring, such as those described in JP-A No. 61-65245; pyrazoloazole couplers having a sulfonamido group in the molecule, such as those described in JP-A No. 61-65246; pyrazoloazole couplers having an alkoxyphenylsulfonamido ballast group, such as those described in JP-A No. 61-147254; pyrazolotriazole couplers having an alkoxy or aryloxy group at the 6-position, such as those described in EP-A 226,849 and 294,785; other couplers described in U.S. Pat. Nos. 3,061,432, 3,725,067, 4,310,619, 4,351,897, 4,556,630, EP 73,636, JP-A Nos. 55-118034, 60-35730, 60-43659, 60-185951 and 61-72238, International Patent Application Laid-Open W088/04795, and Research Disclosure No.24220 and No. 24230.

Examples of yellow couplers for use in the present invention include those described in U.S. Pat. Nos. 3,933,501, 3,973,968, 4,022,620, 4,248,961, 4,314,023, 4,326,024, 4,401,752 and 4,511,649; EP 249,473A, JP-B No. 58-10739, GB Patent No. 1,425,020 and 1,476,760.

Typical examples of dye-forming polymer couplers which are usable herein include those described in U.S. Pat. Nos. 3,451,820, 4,080,211, 4,367,282, 4,409,320 and 4,576,910; EP 341,188A; and GB Patent No. 2,102,137.

Also usable are active methylene compounds having a methylene group adjacent to the carbonyl group therein.

In addition, couplers described in Japanese Patent Application Nos. 9-260336 and 9-271395 are also usable in the present invention. These couplers may be suitably selected and used herein in accordance with the object of the present invention. The couplers may have a polymerizable group.

The details of couplers usable in the present invention are described in, for example, JP-A Nos. 4-201483, 7-223367, 7-223368, 7-323660, 5-278608, 5-297024, 6-18669, 6-18670, and 7-316280. The couplers usable in the present invention are also described in the applicant's own prior Japanese Patent Application Nos. 8-027095, 8-027096, 8-030799, 8-12610, 8-132394, 8-358755, 8-358756 and 9-069990.

The amount of the coupler in the recording layer preferably is 0.02 to 5 g/m², more preferably 0.1 to 4 g/m² and most preferably 0.5 to 3 g/m² in view of its effect. If the amount is smaller than 0.02 g/m², its power to form the intended color will be poor; but if larger than 5 g/m², the coatability of the coating liquid to form the recording layer will be not good.

Also preferably, the amount of the coupler compound is 0.1 to 20 parts by weight, more preferably between 0.5 to 15 parts by weight and most preferably 1 to 10 parts by weight relative to 1 part by weight of the diazonium salt compound to be used in the recording layer. If the amount is smaller than 0.1 part by weight, it is unfavorable since the power of the coupler to form the intended color will be poor and sufficient color can not obtaned; but if larger than 5 g/m²₁ it is also unfavorable since the coatability of the coating liquid to form the recording layer will be not good.

The coupler compound may be dispersed with other components and a water-soluble polymer added thereto within a sand mill or the like to form a solid dispersion. If desired, the coupler compound may be emulsified with a suitable emulsification promoter added thereto and used as an emulsion. The method for the solid dispersion or emulsification is not specifically defined, and any ordinary method can be used. The details of the method can be referred to in JP-A Nos. 59-190886, 2-141279 and 7-17145.

In the present invention, an organic base may be used for promoting the coupling reaction. Examples of the organic base include tertiary amines, piperidines, piperazines, amidines, formamidines, pyridines, guanidines and morpholines.

Examples of the organic bases include piperazines such as N,N′-bis(3-phenoxy-2-hydroxypropyl)piperazine, N,N′-bis[3-(p-methylphenoxy)-2-hydroxypropyl]piperazine, N,N′-bis[3-(p-methoxyphenoxy)-2-hydroxypropyl]piperazine, N,N′-bis(3-phenylthio-2-hydroxypropyl)piperazine, N,N′-bis[3-(β-naphthoxy)-2-hydroxypropyl]piperazine, N-3-(β-naphthoxy)-2-hydroxypropyl-N′-methylpiperazine, 1,4-bis{[3-(N-methylpiperazino)-2-hydroxy]propyloxy}benzene; morpholines such as N-[3-(β-naphthoxy)-2-hydroxy]propylmorpholine, 1,4-bis[(3-morpholino-2-hydroxy)propyloxy]benzene, 1,3-bis[(3-morpholino-2-hydroxy)propyloxy]benzene; piperidines such as N-(3-phenoxy-2-hydroxypropyl)piperidine, N-dodecylpiperidine; and triphenylguanidine, tricyclohexylguanidine, dicyclohexylphenylguanidine, 2-N-methyl-N-benzylaminoethyl 4-hydroxybenzoate, 2-N,N-di-n-butylaminoethyl 4-hydroxybenzoate, 4-(3-N,N-dibutylaminopropoxy)benzenesulfonamide, 4-(2-N,N-dibutylaminoethoxycarbonyl)phenoxy acetamide.

One or more different types of these organic bases may be used either singly or in combination.

These are described in, for example, JP-A Nos. 57-123086, 60-49991, 60-94381, and Japanese Patent Application Nos. 7-228731, 7-235157 and 7-235158.

The amount of the organic base to be used is not specifically defined, but may be 1 to 30 mols per mol of the diazonium salt to be combined with the base.

In order for promoting the color-forming reaction, a color-formation aid may be used.

Examples of the color-formation aid include phenol derivatives, naphthol derivatives, alkoxy-substituted benzenes, alkoxy-substituted naphthalenes, hydroxy compounds, carboxylic acid amide compounds, and sulfonamide compounds. Since these compounds have an ability to lower the melting point of coupler compounds and organic bases or an ability to increase the transmittance of heat through microcapsule walls, it is believed that they ensure higher color density.

(c) Combination of organic metal salt and reducing agent:

Concretely, examples of the organic metal salt include silver salts of long-chain aliphatic carboxylic acids such as silver laurate, silver myristate, silver palmitate, silver stearate, silver arachidate, silver behenate; silver salts of imino group-having organic compounds such as benzotriazole silver salts, benzimidazole silver salts, carbazole silver salts, phthalazinone silver salts; silver salts of sulfur-containing compounds such as S-alkylthioglycolates; silver salts of aromatic carboxylic acids such as silver benzoate, silver phthalate; silver salts of sulfonic acids such as silver ethanesulfonate; silver salts of sulfinic acids such as silver o-toluenesulfinate; silver salts of phosphoric acids such as silver phenylphosphate; silver barbiturate, silver saccharinate; silver salts of salicylaldoximes; and their mixtures.

Among them, preferred examples are silver salts of long-chain aliphatic carboxylic acids; and more preferred is silver behenate. Benenic acid may be combined with silver behenate.

As the reducing agent, any reducing agent disclosed in JP-A No. 53-1020, from page 227, left lower column, line 14 to page 229, right upper column, line 11 can be used properly. Especially preferable reducing agents include mono-, bis-, tris- or tetrakisphenols, mono- or bisnaphthols, di- or polyhydroxynaphthalenes, di- or polyhydroxybenzenes, hydroxymonoethers, ascorbic acid, 3-pyrazolidones, pyrazolines, pyrazolones, reducing saccharides, phenylenediamines, hydroxylamines, reductones, hydroxamines, hydrazides, amdoximes, and N-hydroxyureas.

Among them, especially preferable examples are aromatic reducing agents such as polyphenols, sulfonamidophenols, and naphthols.

For ensuring good transparency of the recording material, it is desirable that the recording layer contains the combination (a) of an electron-donating dye precursor and an electron-receiving compound, or the combination (b) of a diazonium salt and a coupler.

Microcapsule Formation

Methods for encapsulating the color-forming component A or the color-forming component B into microcapsules are described hereinafter. For encapsulating it, employable are any known methods.

For example, an employable method is any of a method of using coacervation of a hydrophilic wall-forming material described in U.S. Pat. Nos. 2,800,457 and 2,800,458; a method of interfacial polymerization as in U.S. Pat. No. 3,287,154, GBP 990,443, JP-B Nos. 38-19574, 42-446, 42-771 and the like; a method of polymer precipitation disclosed in U.S. Pat. Nos. 3,418,250 and 3,660,304; a method of using a wall-forming material of isocyanate polyol as disclosed in U.S. Pat. No. 3,796,669; a method of using a wall-forming material of isocyanate as in U.S. Pat. No. 3,914,511; a method of using a wall-forming material which comprises urea-formaldehyde or urea-formaldehyde-resorcinol as disclosed in U.S. Pat. Nos. 4,001,140, 4,087,376, 4,089,802; a method of using a wall-forming material such as melamine-formaldehyde resin or hydroxypropyl cellulose as disclosed in U.S. Pat. No. 4,025,455; a method of in-situ monomer polymerization as disclosed in JP-B No. 36-9168 and JP-A No. 51-9079; a method of electrolytic dispersion with cooling as disclosed in GB Patent Nos. 952,807 and 965,074; and a method of spray-drying as disclosed in U.S. Pat. No. 3,111,407 and GB Patent No. 930,422.

Though the method is not limited thereto, one preferred example of encapsulation in microcapsules for producing the recording material of the present invention is interfacial polymerization, which is as follows: the color-forming component A is dissolved or dispersed in a hydrophobic organic solvent to prepare an oil phase that is to be the core of each microcapsule; the oil phase is mixed with an aqueous phase of a solution of a water-soluble polymer; the resulting mixture is emulsified with a homogenizer or the like to form oil drops; and then this is heated to cause polymer formation in the interface of the oil drops and the solution, thereby forming a polymer microcapsule wall around each oil drop.

According to the method, microcapsules having a uniform size can be formed within a short period of time, and the recording material containing the microcapsules has good raw-stock storability.

The reactant to form the polymer is added inside and/or outside of oil drops. Specific examples of the polymer include polyurethanes, polyureas, polyamides, polyesters, polycarbonates, urea-formaldehyde resins, melamine resins, polystyrenes, styrene-methacrylate copolymers, and styrene-acrylate copolymers. Among them, preferable examples include polyurethanes, polyureas, polyamides, polyesters, and polycarbonates; and more preferable examples include polyurethanes and polyureas. Two or more polymers may be used in combination.

Examples of the water-soluble polymer include gelatin, polyvinyl pyrrolidone, and polyvinyl alcohol.

For example, when polyurethane is used as microcapsule walls, microcapsule walls of polyurethane are formed as follows: a polyisocyanate and a second substance that reacts with it to form microcapsule walls (for example, polyol, polyamine) are mixed in an aqueous, water-soluble polymer solution (aqueous phase) or in an oily medium to be encapsulated (oil phase), and these are emulsified, and then heated to cause a polymer formation reaction in the interface of the oil drops to thereby form microcapsule walls.

The polyisocyanate and its reactants, polyol and polyamine may be those described in, for example, U.S. Pat. Nos. 3,281,383, 3,773,695, 3,793,268; JP-B Nos. 48-40347, 49-24159; and JP-A Nos. 48-80191, 48-84086.

In preparing microcapsules comprising the color-forming component A in the present invention, the color-forming component A encapsulated may be in any form of solution or solid in the microcapsules.

In cases where the color-forming component A is in the form of a solution in microcapsules, the color-forming component A is encapsulated while it is dissolved in a solvent. In this case, the amount of the solvent is preferably 1 to 500 parts by weight based on 100 parts by weight of the color-forming component A.

If the solubility in the solvent of the color-forming component A that is to be encapsulated is low, a low-boiling point solvent, in which the solubility of the component A is high, may be used as an auxiliary solvent. Examples of the low-boiling-point solvent include ethyl acetate, propyl acetate, isopropyl acetate, butyl acetate, and methylene chloride.

On the other hand, an aqueous solution of a water-soluble polymer is used for the aqueous phase. The above-mentioned oil phase is put into the aqueous phase, and then emulsified in any ordinary manner, using a homogenizer or the like. The water-soluble polymer serves as a dispersion medium that facilitates easy and uniform dispersion of the oil phase and stabilizes the resulting aqueous emulsion. For further unifying and stabilizing the emulsion, a surfactant may be added to at least one of the oil phase or the aqueous phase. The surfactant to be used for the purpose may be any known surfactant for emulsification. The amount of the surfactant, if used, is preferably 0.1 to 5% by weight, more preferably 0.5 to 2% by weight of the oil phase.

The surfactant that may be added to the aqueous phase is suitably selected from anionic or nonionic surfactants that do not react with protective colloid to cause precipitation or coagulation.

Preferred examples of the surfactant include sodium alkylbenzenesulfonates, sodium alkylsulfates, sodium dioctyl sulfosuccinate, and polyalkylene glycols (e.g., polyoxyethylene nonylphenyl ether).

As described above, a water-soluble polymer is provided as a protective colloid is in the aqueous phase to be mixed with an oil phase. The water-soluble polymer may be suitably selected from known anionic polymers, nonionic polymers and ampholytic polymers.

The anionic polymers may be natural substances or synthetic products, and may contain groups such as —COO— or —SO₂—.

Concretely, examples include natural substances such as gum Arabic, alginic acid and pectin; semi-synthetic products such as carboxymethyl cellulose, gelatin derivatives (e.g., phthalated gelatin), sulfated starch, sulfated cellulose and lignin sulfonate; and synthetic products such as maleic anhydride (including its hydrolyzate) based copolymers, acrylic acid (methacrylic acid) based polymers and copolymers, vinylbenzenesulfonic acid based polymers and copolymers, and carboxy-modified polyvinyl alcohol.

Examples of the nonionic polymers include polyvinyl alcohol, hydroxyethyl cellulose, and methyl cellulose.

One example of the ampholytic polymers is gelatin. Among them, preferable examples of the ampholytic polymers are gelatin, gelatin derivatives and polyvinyl alcohol.

The water-soluble polymer may be used in the form of its aqueous solution of 0.01 to 10 wt %.

The color-forming components and all other components to be comprised in the recording layer may be dispersed with a water-soluble polymer, a sensitizer and other color-forming reaction promoters to form a solid dispersion in, for example, a sandmill. More preferably, all the components are previously dissolved in a slightly water-soluble or water-insoluble, high-boiling-point organic solvent, and then mixed with an aqueous polymer solution (aqueous phase) that contains a surfactant and/or a water-soluble polymer serving as a protective colloid, and thereafter emulsified in a homogenizer or the like to form an emulsified dispersion. In this case, a low-boiling-point solvent serving as a dissolution promoter may be used, if desired.

Further, the color-forming components and all other components may be separately emulsified and dispersed; or they may be mixed all, and then dissolved in a high-boiling-point solvent, and thereafter emulsified and dispersed. Preferably, the size of the particles in the emulsified dispersion is at most 1 μm.

Emulsification of the oil phase containing the above-mentioned components and the aqueous phase containing a protective colloid and a surfactant may be processed in any known device used for emulsifying an oil phase and an aqueous phase into fine particles, such as a device which can stir at high speed or a device which can disperse ultrasonically. Examples of any known emulsification device include a homogenizer, Manton Gaulin, ultrasonic disperser, dissolver or Keddy mill.

After the emulsification, the resulting emulsion is kept heated at 30° C. to 70° C. for promoting its capsule wall formation. During the reaction, cohesion of microcapsules must be prevented. Further, in order to lower the probability of collision of microcapsules with each other, water can be added to the reaction system; or the system will be fully stirred.

As the case may be, an additional material may be added to the reaction system to prevent cohesion of microcapsules. With the progress of polymerization, carbon dioxide is formed. The time at which the formation of carbon dioxide is terminated will be nearly the end point of the microcapsule wall formation. In general, microcapsules of intended dye molecules can be formed within a few hours after the start of the reaction.

In the recording material of the present invention, average particle size of the microcapsules is preferably not greater than 20 μm, and more preferably not greater than 5 μm for high resolution of image. If the microcapsules are too small, specific surface area per a predetermined solid to be encapsulated therein will increase, and a large amount of the wall material will be needed. Therefore, it is desirable that the average particle size of the microcapsules is at least 0.1 μm.

Other Components

The recording layer may contain other components. For example, it may contain a known antioxidant such as those described below in order for improving the fastness of images to light and heat and for preventing the images from being yellowed by light after fixing.

Examples of antioxidants usable for the above purpose include those described in EP-A 223,739, 309,401, 309,402, 310,551, 310,552, and 459,416; German Patent Laid-Open No. 3,435,443; JP-A Nos. 54-48535, 62-262047, 63-113536, 63-163351, 2-262654, 2-71262, 3-121449, 5-61166, 5-119449; and U.S. Pat. Nos. 4,814,262, and 4,980,275.

In addition, the recording layer may contain any known additives generally used in thermal recording materials and pressure-sensitive recording materials.

Examples of the additives include those described in JP-A Nos. 60-107384, 60-107383, 60-125470, 60-125471, 60-125472, 60-287485, 60-287486, 60-287487, 60-287488, 61-160287, 61-185483, 61-211079, 62-146678, 62-146680, 62-146679, 62-282885, 63-051174, 63-89877, 63-88380, 63-088381, 63-203372, 63-224989, 63-251282, 63-267594, 63-182484, 1-239282, 4-292685, 4-291684, 5-188687, 5-188686, 5-110490, 5-1108437, and 5-170361; and JP-B Nos. 48-043294, and 48-033212.

The recording layer may contain a binder such as any known water-soluble polymer compound and latex.

Examples of the water-soluble polymer compound include methyl cellulose, carboxymethyl cellulose, hydroxyethyl cellulose, hydroxypropyl cellulose, starch derivatives, casein, gum arabic, gelatin, ethylene-maleic anhydride copolymer, styrene-maleic anhydride copolymer, polyvinyl alcohol, epichlorohydrin-modified polyamides, isobutylene-maleic anhydride-salicylic acid copolymer, polyacrylic acid, polyacrylamide, and their modified derivatives. Examples of the latex include styrene-butadiene rubber latex, methyl acrylate-butadiene rubber latex, and vinyl acetate emulsion.

The recording layer may further contain any known organic and inorganic pigments.

Concrete examples include kaolin, calcined kaolin, talc, agalmatolite, diatomaceous earth, calcium carbonate, aluminium hydroxide, magnesium hydroxide, zinc oxide, lithopone, amorphous silica, colloidal silica, calcined gypsum, silica, magnesium carbonate, titanium oxide, alumina, barium carbonate, barium sulfate, mica, microballoons, urea-formalin filler, polyester particles, and cellulose filler.

The recording layer may further contain other various additives known in the art such as wax, antistatic agent, defoaming agent, electroconductive agent, fluorescent dye, surfactant, UV absorbent and its precursors.

Formation of Recording Layer

The recording layer may be formed by applying a coating liquid for the recording layer onto a support followed by drying.

Examples of the solvent usable in the coating liquid for the recording layer include water; alcohols such as methanol, ethanol, n-propanol, isopropanol, n-butanol, sec-butanol, methyl cellosolve, and 1-methoxy-2-propanol; halogen-containing solvents such as methylene chloride and ethylene chloride; ketones such as acetone, cyclohexanone, and methyl ethyl ketone; esters such as methyl cellosolve acetate, ethyl acetate, and methyl acetate; toluene, and xylene. One or more of these solvents may be used either singly or in combination. Of those, especially preferred is water.

For applying the coating liquid onto a support, a usable device is any of blade coaters, rod coaters, knife coaters, roll doctor coaters, reverse roll coaters, transfer roll coaters, gravure coaters, kiss roll coaters, curtain coaters, and extrusion coaters.

The coating method can be referred to those described in Research Disclosure, Vol. 200 (December 1980, Item 20036, XV).

The thickness of the recording layer is preferably 0.1 to 50 μm, more preferably 5 to 35 μm.

(Support)

As the support, any and every type of paper support generally used for conventional pressure-sensitive or thermal copying paper or dry or wet diazo copying paper can be usable.

Concrete examples include acid paper, neutral paper, coated paper, plastic film-laminated paper such as those laminated with polyethylene, synthetic paper, and plastic films such as polyethylene terephthalate or polyethylene naphthalate films. In cases where the support is transparent, the recording material comprising the support can be exposed to light from the side of its support, in the step of latent image formation or image fixation.

The support may contain various additives such as a fluorescent brightener and pigment.

(Other Layers)

Protective Layer

The recording material of the present invention may have a protective layer on the recording layer. If desired, the protective layer may have a laminate structure of two or more layers.

As a material used for forming the protective layer, usable examples include water-soluble polymer compounds such as polyvinyl alcohol, carboxy-modified polyvinyl alcohol, vinyl acetate-acrylamide copolymer, silicon-modified polyvinyl alcohol, starch, modified starch, methyl cellulose, carboxymethyl cellulose, hydroxymethyl cellulose, gelatins, gum arabic, casein, hydrolyzed styrene-maleic acid anhydride copolymer, hydrolyzed styrene-maleic acid copolymer half-ester, hydrolyzed isobutylene-maleic anhydride copolymer, polyacrylamide derivatives, polyvinyl pyrrolidone, sodium polystyrenesulfonate, sodium alginate; and latexes such as styrene-butadiene rubber latex, acrylonitrile-butadiene rubber latex, methyl acrylate-butadiene rubber latex, vinyl acetate emulsion.

If desired, the water-soluble polymer compound used for the protective layer may be crosslinked for further improving the storage stability of the recording material. Any known crosslinking agent may be used for the crosslinking.

Concrete examples of the crosslinking agent include water-soluble precondensates such as N-methylolurea, N-methylolmelamine, and urea-formalin; dialdehyde compounds such as glyoxal, glutaraldehyde; inorganic crosslinking agents such as boric acid, borax; and polyamidepichlorohydrin.

If desired, the protective layer may be cured through exposure to electronic rays. Also if desired, the protective layer may contain any known pigment, metal soap, wax, surfactant, fluorescent brightener, and UV absorbent.

A coated amount of the protective layer to be formed is preferably 0.2 to 5 g/m² more preferably 0.3 to 3.5 g/m² and most preferably 0.5 to 2 g/m², and the thickness thereof is preferably 0.2 to 5 μm, more preferably 0.3 to 3.5 μm and most preferably 0.5 to 2 μm.

Back coat Layer

The recording material of the present invention may have a back coat layer for correcting a curl balance of the support thereof and for preventing chemicals and others from penetrating into the back surface thereof.

The back-coat layer may be formed in the same manner as those for forming the protective layer. In addition, by combining a separate paper, a release sheet may be attached to the back surface via an adhesive layer provided between the back surface and the released sheet, and may be used as labels.

Intermediate layer

In cases where plural recording layers to form different colors are laminated on the support, an intermediate layer which optionally contains a filter dye may be disposed between the adjacent monochromatic recording layers.

The intermediate layer essentially comprises a binder, and optionally contains a curing agent and other additives such as polymer latex, mica, UV absorbent, etc. When the filter dye is used in the intermediate layer, the above-mentioned spectral sensitizing dyes may be selected and used as the filter dye. Preferably, the filter dye is so selected that the filter dye has a light absorption wavelength range, which is the same as those of the spectral sensitizing dyes existing in the recording layer just above the intermediate layer, for obtaining sharp images.

The filter dye is, after having been formed into an emulsion through a method of oil-in-water dispersion or polymer dispersion, added to the desired layer, especially to the desired intermediate layer.

For forming its emulsion through the method of oil-in-water dispersion, for example, the filter dye is first dissolved in any one of a high-boiling-point solvent having a boiling point of not lower than 175° C. and a low-boiling-point solvent having a boiling point in a range of 30 to 160° C., or in a mixture of the two, and then finely dispersed with a surfactant in an aqueous medium such as water, aqueous gelatin or aqueous polyvinyl alcohol.

As a high-boiling-point solvent used for the intermediate layer, usable are those described in U.S. Pat. No.2,322,027. The high-boiling-point solvent and an auxiliary solvent may be the same as those used in microcapsule production.

In preparing the dye emulsion, the dispersion may be accompanied by phase inversion. If desired, the auxiliary solvent used may be removed or reduced through distillation, noodle washing or ultrafiltration, before the dye emulsion is used for coating.

The details of the process of a polymer dispersion method and curing and the examples of latex for dipping are described in, for example, U.S. Pat. No. 4,199,383; German Patent Application (OLS) Nos. 2,541,274, and 2,541,230; JP-A Nos. 49-74538, 51-59943, and54-32552; and Research Disclosure, Vol. 148 (August 1976, Item 14850).

As the latex, for example, preferred are latexes of copolymers of acrylates or methacrylates such as ethyl acrylate, n-butyl acrylate, n-butyl methacrylate or 2-acetacetoxyethyl methacrylate, or latexes of copolymers of other acid monomers such as acrylic acid or 2-acrylamido-2-methylpropanesulfonic acid.

Antihalation Layer and the like

One polymer layer of, for example, gelatin or PVA to lower the oxygen transmittance through the recording layer may be provided between the support and the recording layer. The polymer layer can prevent the images formed from being faded through photo-oxidation.

An antihalation layer may be provided between the support and the recording layer, or on the support opposite to the recording layer when the support is transparent. Preferably, the antihalation layer is bleachable by light or heat, as the whiteness of the background of the recording material is increased. When the antihalation layer is bleachable by light, for example, employable for it is a combination of a dye and a boron compound. When the antihalation layer is bleached by heat, for example, employable for it is a system of dye bleaching after color is formed in the presence of a base or a nucleophilic agent.

In cases where the recording material of the present invention is a material for full-color image formation, in general, plural recording layers to form different colors are laminated on a support. In this, each layer of the plural recording layers to form different colors contains a color-forming component A and the like in microcapsules, and a color-forming component B and the like outside the microcapsules. Each of the color-forming components A can form different colors. These components A and B may be comprised in single layer or a layer having a structure of plural layers. (The components inside and outside the microcapsules may be opposite to the above.) When exposed to light, the plural recording layers in the material are individually sensitized to different wavelengths to form a multi-color image.

When plural photopolymerization initiators sensitive to different wavelengths are used in the recording material, different latent images are formed in accordance with the light of different wavelengths. Therefore, when the plural color-forming components to form different colors or hues (for example, yellow, magenta, cyan) and the photopolymerization initiators are used according to their absorption wavelengths (for the same color, or complementary colors, or even any other colors), the recording material can form multi-color, especially full-color images. The photopolymerization initiators and the color-forming components corresponding to each other may be in different layers for color separation, or may be both in one layer. In cases where the initiator and the color-forming component are both in one layer, it is desirable that they are encapsulated in microcapsules. If the initiator and the color-forming component are both in one layer, the multi-color, especially full-color recording material is easy to fabricate.

[Image Recording Method]

The recording material of the present invention may be processed in any known image-recording method.

One preferred method of image formation wherein the recording material of the present invention is used is described below.

An image can be formed on the recording material through a latent image-forming step of imagewise exposing the recording layer of the material to light which is absorbed by the dye in the layer but not by the borate compound of formula (I) therein, to thereby make the polymerizable compound in the layer polymerized by the action of the radicals generated in the area exposed to the light to form a latent image composed of the non-exposed portions of the layer, followed by a step of visualizing the latent image by applying heat and/or pressure to the entire surface of the recording layer to thereby make the color-forming component A react with the color-forming component B in the layer.

In case where the recording material to be processed in the manner as above comprises a recording layer containing different types of organic dyes, a multi-color image is readily formed on the material. In addition, in case where the different types of organic dyes in the material are those for three primary colors of yellow, magenta and cyan, a full-color image is readily formed on the material. The absorption wavelengths of the dyes to be selected for such full-color image formation may be selected in a broad range of from UV to IR rays, and the image thus formed on the material has little color mixing therein.

The image-recording process is described in detail hereinafter.

When the dye in the material is exposed to light in the latent image-forming step of the process, the dye is excited and interacts with the borate compound in the material, whereby the borate compound releases a radical. The thus-released radical acts to polymerize a polymerizable compound which exists in the material. The polymerizable compound means the color-forming component B that has a polymerizable group, microcapsule-forming oil having a polymerizable group, the above-mentioned radical-polymerizable compound existing outside the microcapsules, and the like. They are or at least one of them is polymerized by the action of the radical. As a result, the resulting polymer thus formed in the exposed area of the material prevents the contact between the color-forming component A and the color-forming component B in the exposed area in the next image-visualizing step in which heat and/or pressure is applied to the material. In other words, in the image-visualizing step, the color-forming component A is brought into contact with the color-forming component B only in the non-exposed area, and color is formed in that area.

Regarding the wavelength range of a light source to be employed, any desired light source can be suitably selected from a broad range of UV to IR rays, in accordance with the dye and the borate compound used in the recording material. As the light source, for example, usable are semiconductor lasers, LEDs, xenon lamps, fluorescent lamps, mercury lamps and the like. Depending on the organic dyes used, two or more light sources having different wavelength ranges may be used.

In general, the recording material is exposed to light on the side of the recording layer thereof, but when the support of the material is transparent, it may also be exposed to light on the side of the support.

The quantity of light necessary for latent image formation may be such that it is enough to start the polymerization of the radical-polymerizable compound in the recording material, and it is relatively small. Accordingly, much light is unnecessary for image formation on the material, and inexpensive light sources are employable for it. Therefore, one advantage of the recording material of the present invention is that high-speed image recording on the material is possible.

In the latent image-visualizing step, heat and/or pressure is applied to the entire surface of the recording layer to such a degree that the microcapsules in the layer are broken or the reactants can penetrate into the microcapsules through their walls. The concrete condition of the temperature, the pressure and/or the time for the treatment may be suitably determined depending on the material of the microcapsule walls and the like. Preferably, the heating temperature is in a range of 50 to 250° C. and more preferably 70 to 150° C. In case where heat is applied to the entire surface of the recording layer, examples of the heat source employable for heating may include any of heat rollers, thermal heads, thermal stamps, near-IR rays (lasers), IR rays (lasers) and the like. In case where pressure is applied to the entire surface of the recording layer, examples of employable devices include any of pressure rollers or pressure pens.

The thus-formed image is preferably fixed by further exposing the entire surface of the recording layer to light in a fixing step. In the step of additional exposure to light, the spectral sensitizing dye that originally exists in the recording layer is bleached by the radicals derived from the borate compound, and the degree of whiteness of the background area (this was exposed to light in the latent image-forming step) increases. In the fixing step in which the image-formed layer is further exposed to light, the polymerizable compound which is not yet polymerized and remains in the layer is polymerized, and the image is more firmly fixed by the resulting polymer. This is another advantage of the recording material of the present invention.

In the fixing step, the material may be exposed to any light having a wavelength falling within a range of from 300 to 1000 nm. As the case may be, the material may be exposed to both of light which is the absorption wavelength of the dye and light which is the absorption wavelength of the borate compound. The light source for it may be any ordinary one, including lasers, xenon lamps, fluorescent lamps, mercury lamps and all others. of course, the light source in this step is not for image recording on the material but is for exposing the entire surface of the recording layer of the material. Therefore, even when a high-power light source is used in this step, the light source is not expensive, and therefore not increasing the cost of image formation and not interfering with the capability of high-speed image formation on the material.

### EXAMPLES

The present invention is described more concretely with reference to the following Examples, which, however, are not intended to restrict the scope of the present invention.

### Example 1

### Preparation of Electron-Donating Leuco-Dye Microcapsule Suspension (I)

8.9 g of an electron-donating leuco dye (1) having a structural formula mentioned below which can form magenta was dissolved in 16.9 g of ethyl acetate. 20 g of a capsule wall-forming material (trade name: Takenate D-110, it was manufactured by Takeda Chemical Industry, Ltd.) and 2 g of a capsule wall-forming material (trade name: Millionate MR200, it was manufactured by Nippon Polyurethane Industry, Ltd.).

The resulting solution was added to a liquid mixture of 42 g of 8% phthalated gelatin and 1.4 g of 10% sodium dodecylbenzenesulfonate solution, and dispersed at 20° C. to prepare an emulsion. To the resulting emulsion, added were 14 g of water and 72 g of 2.9% aqueous solution of tetraethylenepentamine, and heated at 60° C. with stirring. After 2 hours, obtained was a suspension of microcapsules having an average particle diameter of 0.5 μm, in which a core of each microcapsule was formed by the electron-donating leuco-dye (1).

Electron-Donating Leuco-Dye (1):

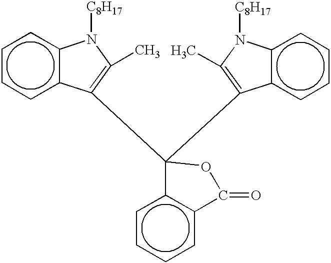

[Preparation of Photopolymerizable Composition Emulsion (I)]

Photopolymerizable composition emulsion (I) comprises a borate compound-containing liquid (A) and a dye-containing liquid (B) mentioned below.

Preparation of Borate Compound-Containing Solution (A)

0.5 g of a borate compound (Compound No. 1) having a structural formula mentioned below, and 2.5 g of tricresyl phosphate were dissolved in 4.5 g of isopropyl acetate (having a solubility in water of about 4.3%); and the resulting solution was added to a mixture of 7.8 g of 15% aqueous solution of gelatin, 0.4 g of 10% aqueous solution of surfactant (1) having a structural formula mentioned below and 3.7 g of water, and emulsified in a homogenizer (manufactured by Nippon Seiki Co., Ltd.) for 5 minutes at 10,000 rpm to prepare a borate compound-containing solution (A).

Borate Compound (Compound No. 1):

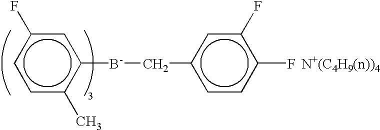

Surfactant (1):

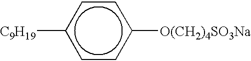

Preparation of Dye-Containing Solution (B)

To a mixture of 0.498 g of a spectral sensitizing dye having a structural formula mentioned below, 0.498 g of a sensitivity aid (1) having a structural formula mentioned below, and 5.25 g of isopropyl acetate (having a solubility in water of about 4.3%), added was 83 g of an electron-receiving compound (1) having a polymerizable group and having a structural formula mentioned below.

The resulting solution was added to a mixture of 109.1 g of 15% aqueous solution of gelatin, 0.8 g of 2% aqueous solution of surfactant (1) mentioned above, and 4.0 g of 2% aqueous solution of surfactant (2) having a structural formula mentioned below, and emulsified in a homogenizer (manufactured by Nippon Seiki Co., Ltd.) for 5 minutes at 10,000rpm to prepare a dye-containing solution (B).

Spectral Sensitizing Dye:

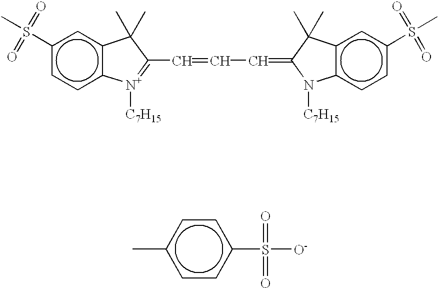

Polymerizable, Electron-Receiving Compound (1):

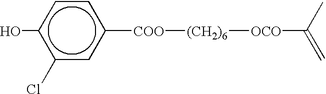

sensitivity aid (1)

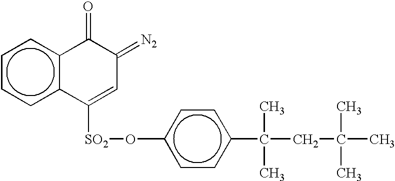

Surfactant (2):

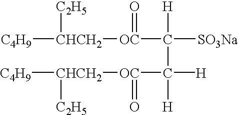

[Preparation of Coating Liquid (I) for Photosensitive Thermal Recording Layer]

2 g of the electron-donating leuco-dye microcapsule suspension (I), 2.25 g of the borate compound-containing solution (A), 7.36 g of the dye-containing solution (B), and 0.41 g of 15% aqueous solution of gelatin were mixed to prepare a coating liquid (I) for photosensitive thermal recording layer.

[Preparation of Coating Liquid for Protective Layer]

4.5 g of 10% aqueous solution of gelatin, 4.5 g of distilled water, 0.5 g of 2% aqueous solution of surfactant (3) having a structural formula mentioned below, 0.3 g of 2% aqueous solution of surfactant (4) having a structural formula mentioned below, 0.5 g of 2% aqueous solution of vinylsulfone based compound (hardener), and Syloid 72 (manufactured by Fuji-Devison Chemical, Ltd.) to give a dry coat amount of 50 mg/m², and 1 g of Snowtex N were mixed to prepare a coating liquid for protective layer.

Surfactant (3):

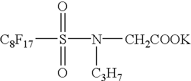

Surfactant (4):

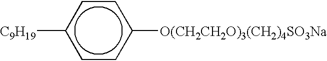

[Preparation of Photosensitive Thermal Recording Material]

Using a coating bar, the coating liquid (I) for photosensitive thermal recording layer was applied onto a support of a white pigment-filled polyester film (Lumirror E-68L, it was manufactured by Toray Industries, Inc.) having a thickness of 100 μm, and dried to form thereon a photosensitive thermal recording layer having a dry weight of 6 g/m².

Also using a coating bar, the coating liquid for protective layer prepared in Example 1 was applied onto the recording layer, and dried to form thereon a protective layer having a dry weight of 2 g/m². Thus was produced a photosensitive thermal recording material of the present invention.

With a light source of 657 nm semiconductor laser which was facing a protective layer, the photosensitive thermal recording material was exposed to light such that an image of a step wedge was formed through which the light energy was varied in a predetermined order and was at most 15 mJ/cm².

Next, the material thus having a latent image formed thereon was heated on a hot plate at 120° C. for 5 seconds, and then wholly exposed to a high power 58,000 lux film viewer for 30 seconds. Having been thus exposed, the material had a sharp, step-wedge color image formed thereon, and its background area was white and good.

<Evaluation of Sensitivity>

The sensitivity of the recording material was determined as follows: An energy difference between the energy which the recording material needed to form one step of a step-wedge image thereon through exposure wherein the exposure for the step is fixed, and the energy which the recording material needed to form a background area (that is, the energy needed for forming the background area—the energy needed for forming the one step of the step-wedge image) is measured and calculated. The difference indicates the sensitivity of the recording material. Recording materials that need a lower value of the energy have a higher sensitivity. The data are shown in Table 2.

<Measurement of Dmin>

The background fog (Dmin) of the material was measured with a Macbeth transmission densitometer (manufactured by Macbeth Inc.) or with a Macbeth reflection densitometer (manufactured by Macbeth Inc.). The data are shown in Table 2.

### Examples 2 to 7

Coating liquids (II) to (VII) for photosensitive thermal recording layer were prepared in the same manner as in Example 1, except that each of borate compounds Nos. 2 to 7 shown in Table 1 below was used instead of the borate compound No. 1. Using these, photosensitive thermal recording materials (II) to (VII) of the present invention were produced also in the same manner as in Example 1.

TABLE 1

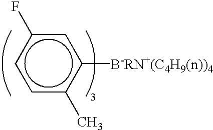

| | Borate | |
|---|---|---|
| | Compound No. | R of the above formula |
| Example 2 | 2 | —C₂H₅ |
| Example 3 | 3 | 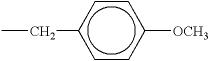 |
| Example 4 | 4 | —C₆H₁₃(n) |
| Example 5 | 5 | 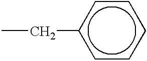 |
| Example 6 | 6 | —C₃H₇(n) |
| Example 7 | 7 | —C₅H₁₁(n) |
| Comp. Ex. 1 | 8 | —CH₂C₄H₉(t) |
| Comp. Ex. 2 | 9 | 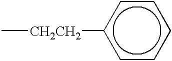 |
| Comp. Ex. 3 | 10 | —C₄H₉(n) |
| Comp. Ex. 4 | 11 | —C₃H₇(i) |
| Comp. Ex. 5 | 12 | —C₅H₁₁(i) |

### Comparative Examples 1 to 5

Coating liquids (VIII) to (XII) for photosensitive thermal recording layers were prepared in the same manner as in Example 1, except that each of borate compounds Nos. 8 to 12 shown in Table 1 above was used in preparing the photopolymerizable compositions instead of the borate compound No. 1. Using these, photosensitive thermal recording materials (VIII) to (XII) were produced also in the same manner as in Example 1.

The photosensitive thermal recording materials of Examples 2 to 7 and Comparative Examples 1 to 5 were processed and evaluated in the same manner as in Example 1. The data are shown in Table 2.

TABLE 2

| | Photosensitive | | | |
|---|---|---|---|---|
| | Thermal | | | |
| | Recording | Melting | Sensitivity | |
| | Material | Point (° C.) | (mJ/cm²) | Dmin |
| Example 1 | (I) | 95.6 | 0.31 | 0.09 |
| Example 2 | (II) | 103.4 | 0.37 | 0.10 |
| Example 3 | (III) | 110.7 | 0.21 | 0.11 |
| Example 4 | (IV) | 120.7 | 0.30 | 0.10 |
| Example 5 | (V) | 127.7 | 0.41 | 0.22 |
| Example 6 | (VI) | 130.4 | 1.00 | 0.11 |
| Example 7 | (VII) | 135.5 | 0.48 | 0.10 |
| Comp. Ex. 1 | (VIII) | 143.5 | 0.73 | 0.16 |
| Comp. Ex. 2 | (IX) | 145.4 | 2.70 | 0.28 |
| Comp. Ex. 3 | (X) | 167.3 | 6.88 | 0.51 |
| Comp. Ex. 4 | (XI) | 174.6 | 8.23 | 1.12 |
| Comp. Ex. 5 | (XII) | 177.2 | 11.32 | 1.19 |

From Table 2, it is understood that the samples containing the borate compound having a melting point of not more than 140° C. of the present invention have high sensitivity and good color erasability. As opposed to these, the samples of Comparative Examples 1 to 5, in which the borate compound used has a melting point of higher than 140° C., have low sensitivity and their color erasability is not good. This is supported by the data in Table 2.

The photopolymerizable composition, in which is used a borate compound having a low melting point, and the recording material containing the photopolymerizable composition of the present invention have high sensitivity, good color erasability and good storability.

What is claimed is:

1. A photopolymerizable composition comprising at least a radical-polymerizable compound and a photopolymerization initiator, wherein the photopolymerization initiator contains a borate compound of the following general formula (I), the borate compound having a melting point of at most 140° C.: 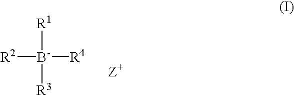
wherein R¹, R², R³ and R⁴ each independently represent an alkyl group, aryl group, heterocyclic group, or silyl group; and Z⁺ represents a cation.

2. The photopolymerizable composition according to claim 1, the photopolymerizable composition further comprises a dye.

3. The photopolymerizable composition according to claim 1, wherein the melting point of the borate compound is at most 130° C.

4. The photopolymerizable composition according to claim 1, wherein the melting point of the borate compound is in the range of 50° C. to 120° C.

5. The photopolymerizable composition according to claim 1, wherein R¹, R² and R³ each represent an aryl group, and R⁴ represents an alkyl group.

6. The photopolymerizable composition according to claim 5, wherein at least one of R¹, R² and R³ is an aryl group that has an electron-attracting group.

7. The photopolymerizable composition according to claim 1, wherein Z⁺ represent a cation selected from the group consisting of alkali metals, alkaline earth metals, transition metals, quaternary ammoniums, dye cations, and cationic transition metal-coordinated complex compounds.

8. The photopolymerizable composition according to claim 1, wherein Z⁺ is a cation selected from the group consisting of ammonium, tetraalkylammoniums, dye cations, cationic dyes, benzyltrialkylammoniums and trialkylammoniums.

9. The photopolymerizable composition according to claim 1, wherein Z⁺ is a cation selected from the group consisting of a phosphonium ion and an ammonium ion represented by the following formulae, poly-form ion of the phosphonium ion and ammonium ion, a bis-form ion of the phosphonium ion and the ammonium ion, and the ammonium ion and the phosphonium ion substituted with a neutral dye, and the phosphonium ion and ammonium ion substituted with a colorless electron acceptor: 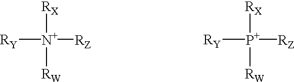
wherein R_{w}, Rₓ, R_{y} and R_{z} each independently represent a hydrogen atom, or an unsubstituted or substituted alkyl, cycloalkyl, alkenyl, phenyl or arylalkyl group.

10. The photopolymerizable composition according to claim 1, wherein the composition comprises the borate compound in an amount of 1 to 20% by weight based on the total weight of the radical-polymerizable compound.

11. The photopolymerizable composition according to claim 1, wherein at least one of R¹, R², R³ and R⁴ is a group substituted with a substituent.

12. A recording material comprising a support and at least one recording layer, wherein the recording layer contains a color-forming component A, a color-forming component B that reacts with the color-forming component A for forming color, and a photopolymerizable composition, the photopolymerizable composition including at least a radical-polymerizable compound and a photopolymerization initiator, and the photopolymerization initiator which include a borate compound of the following general formula (I), the borate compound having a melting point of not lower than 140° C.: 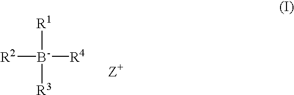
wherein R¹, R², R³ and R⁴ each independently represent an alkyl group, aryl group, heterocyclic group, or silyl group; and Z⁺ represents a cation.

13. The recording material according to claim 12, wherein the photopolymerizable composition further comprises a dye.

14. The recording material according to claim 12, wherein both the color-forming component A and the color-forming component B are transparent material so as to be substantially colorless.

15. The recording material according to claim 12, further comprising at least one other recording layer, the recording layers being laminated with one another and forming different color to one another.

16. The recording material according to claim 12, wherein the combination of the color-forming component A and the color-forming component B is a combination selected from the group consisting of a combination of an electron-donating dye precursor and an electron-receiving compound, a combination of a diazonium salt compound and a coupler, a combination of an organic metal salt and a reducing agent, and a combination of a deprotecting agent and a precursor selected from protected dye precursors and leuco-dye precursors.

17. The recording material according to claim 12, wherein the recording layer comprises microcapsules.

18. The recording material according to claim 12, wherein the recording layer comprises at least one material selected from the group consisting of antioxidants, binders, organic pigments, inorganic pigments, waxes, antistatic agents, defoaming agents, electroconductive agents, fluorescent dyes, surfactants, UV absorbents and respective precursors thereof.

19. A method for forming an image comprising the steps of:
preparing a recording material which has a support and at least one recording layer, the recording layer containing a color-forming component A, a color-forming component B that reacts with the color-forming component A for forming a color, and a photopolymerizable composition, the photopolymerizable composition including at least a photopolymerization initiator which includes a borate compound of the following general formula (I), the borate compound having a melting point of at most 140° C.: 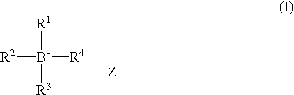
wherein R¹, R², R³ and R⁴ each independently represent an alkyl group, aryl group, heterocyclic group, or silyl group, and Z⁺ represents a cation;
forming a latent image on the recording layer by imagewise exposing the recording layer to light such that non-exposed portions of the layer form the latent image; and
visualizing the latent image by applying at least one of heat and pressure to substantially an entire surface of the recording layer so as to make the color-forming component A react with the color-forming component B at the non-exposed portion.

20. The method for forming an image according to claim 19, further comprising a step of fixing the image by exposing the entire surface of the image-recorded layer to light.
